(19) United States
(12) Patent Application Publication
(10) Pub. No.: US 2025/0286650 A1
(43) Pub. Date: Sep. 11, 2025

(54) REMAPPING OF MESSAGES TO CODEWORDS FOR NONUNIFORM MESSAGE TRANSMISSION

(71) Applicant: QUALCOMM Incorporated, San Diego, CA (US)

(72) Inventors: Pinar SEN, San Diego, CA (US); Wei YANG, San Diego, CA (US); Jing JIANG, San Diego, CA (US); Kirill IVANOV, La Jolla, CA (US)

(21) Appl. No.: 18/597,706

(22) Filed: Mar. 6, 2024

(51) Int. Cl. H04L 1/00; H04W 28/04

(52) U.S. Cl. CPC H04L 1/0009; H04L 1/0033; H04W 28/04

(57) ABSTRACT

Methods, systems, and devices for wireless communications are described. A first device may obtain a first message bit combination that includes a first quantity of bits for inclusion in a message to be transmitted by the first wireless device. The first device may encode the first set of bits using a first subcode that is mapped to the first message bit combination of a set of message bit combinations in accordance with a subcode mapping scheme, each of the set of message bit combinations having the first quantity of bits. The subcode mapping scheme may be based on a set of communication probability metrics for the set of message bit combinations and a set of error probability metrics for a set of subcodes that comprises the first subcode. The first device may output the message comprising the encoded first set of bits.

### FIELD OF TECHNOLOGY

The following relates to wireless communications, including remapping of messages to codewords for nonuniform message transmission.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support remapping of messages to codewords for nonuniform message transmission. For example, the described techniques provide for a first device obtaining a first message bit combination that includes a first quantity of bits for inclusion in the first message to be transmitted by the first wireless device. The first device may encode the first set of bits using a first subcode that is mapped to the first message bit combination of a set of message bit combinations in accordance with a subcode mapping scheme. Each of the set of message bit combinations may have the first quantity of bits. The subcode mapping scheme may be based on a set of communication probability metrics for the set of message bit combinations and a set of error probability metrics for a set of subcodes that comprises the first subcode. The first device may output the message comprising the encoded first set of bits.

A method by a first wireless device is described. The method may include obtaining a first set of bits having a first message bit combination that includes a first quantity of bits for inclusion in a message to be transmitted by the first wireless device, encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode, and outputting the message including the encoded first set of bits.

A first wireless device is described. The first wireless device may include one or more memories storing processor executable code, and one or more processors coupled with the one or more memories. The one or more processors may individually or collectively be operable to execute the code to cause the first wireless device to obtain a first set of bits having a first message bit combination that includes a first quantity of bits for inclusion in a message to be transmitted by the first wireless device, encode the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode, and output the message including the encoded first set of bits.

Another first wireless device is described. The first wireless device may include means for obtaining a first set of bits having a first message bit combination that includes a first quantity of bits for inclusion in a message to be transmitted by the first wireless device, means for encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode, and means for outputting the message including the encoded first set of bits.

A non-transitory computer-readable medium storing code is described. The code may include instructions executable by one or more processors to obtain a first set of bits having a first message bit combination that includes a first quantity of bits for inclusion in a message to be transmitted by the first wireless device, encode the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode, and output the message including the encoded first set of bits.

In some examples of the method, first wireless devices, and non-transitory computer-readable medium described herein, the subcode mapping scheme indicates a set of multiple indexes, a first index of the set of multiple indexes maps the first set of bits to the first message bit combination, and the set of multiple indexes may be based on an ordering of the set of multiple communication probability metrics for the set of multiple message bit combinations.

In some examples of the method, first wireless devices, and non-transitory computer-readable medium described herein, the subcode mapping scheme maps the set of multiple message bit combinations ordered in accordance with first sequential order of a respective communication probability metric for each of the set of multiple message bit combinations, to the set of multiple subcodes ordered in accordance with a second sequential order of a respective error probability metric for each of the set of multiple subcodes and the second sequential order may be reverse of the first sequential order.

In some examples of the method, first wireless devices, and non-transitory computer-readable medium described herein, the subcode mapping scheme maps one or more first message bit combinations, with higher communication probability metrics than one or more second message bit combinations, to one or more first subcodes with lower error probability metrics than one or more second subcodes, and the one or more second message bit combinations, with lower communication probability metrics than the one or more first message bit combinations, to the one or more second subcodes with higher error probability metrics than the one or more first subcodes.

In some examples of the method, first wireless devices, and non-transitory computer-readable medium described herein, the subcode mapping scheme maps the set of multiple message bit combinations ordered sequentially, using a respective communication probability metric for each of the set of multiple message bit combinations, to a set of multiple sequential indexes, and each index of the set of multiple sequential indexes to a respective subcode of the set of multiple subcodes ordered sequentially using a respective error probability metric.

In some examples of the method, first wireless devices, and non-transitory computer-readable medium described herein, the set of multiple subcodes may be ordered such that a subcode with a lowest error probability metric among the set of multiple subcodes may be mapped to a lowest index of the set of multiple sequential indexes resulting in a least significant bit of the lowest index being applicable to the subcode with the lowest error probability metric.

In some examples of the method, first wireless devices, and non-transitory computer-readable medium described herein, the set of multiple message bit combinations may be ordered sequentially from a highest communication probability metric to a lowest communication probability metric, each respective set of bits for each index of the set of multiple sequential indexes may be ordered from a most significant bit (MSB) to a least significant bit (LSB) such that a first bit position in each respective set of bits may be the MSB and a last bit position in each respective set of bits may be the LSB, and the set of multiple subcodes may be ordered from a highest error probability metric to a lowest error probability metric.

In some examples of the method, first wireless devices, and non-transitory computer-readable medium described herein, the set of multiple message bit combinations may be ordered sequentially from a highest communication probability metric to a lowest communication probability metric, each respective set of bits for each index of the set of multiple sequential indexes may be ordered from a LSB to a MSB such that a first bit position in each respective set of bits may be the LSB and a last bit position in each respective set of bits may be the MSB, and the set of multiple subcodes may be ordered from a lowest error probability metric to a highest error probability metric.

In some examples of the method, first wireless devices, and non-transitory computer-readable medium described herein, the set of multiple message bit combinations may be ordered sequentially from a highest communication probability to a lowest communication probability, each respective set of bits for each index of the set of multiple sequential indexes may be ordered from a LSB to a MSB such that a first bit position in each respective set of bits may be the LSB and a last bit position in each respective set of bits may be the MSB, and the set of multiple subcodes may be included in a generator matrix with a modified Reed Muller code ordering.

In some examples of the method, first wireless devices, and non-transitory computer-readable medium described herein, the subcode mapping scheme maps a MSB of each index of the set of multiple sequential indexes to a first bit location with lower reliability than a second bit location in each subcode of the set of multiple subcodes, and a LSB of each index of the set of multiple sequential indexes to the second bit location with a higher reliability than the first bit location, each subcode may be a respective polar code, and the subcode mapping scheme results in a respective MSB of each index being mapped to a least reliable bit location in a respective polar code and a respective LSB of each index being mapped to a respective most reliable bit location in the respective polar code.

In some examples of the method, first wireless devices, and non-transitory computer-readable medium described herein, the subcode mapping scheme maps a cyclic redundancy check (CRC) bit to a respective most reliable location in each polar code of the set of multiple subcodes.

In some examples of the method, first wireless devices, and non-transitory computer-readable medium described herein, the subcode mapping scheme maps a MSB of each index of the set of multiple sequential indexes to a first bit location with lower reliability than a second bit location in each subcode of the set of multiple subcodes, and a LSB of each index of the set of multiple sequential indexes to the second bit location with a higher reliability than the first bit location, each subcode may be a respective polar code, and the subcode mapping scheme results in a respective MSB of each index being mapped to a least reliable bit location in a respective polar code and a respective LSB of each index being mapped to a respective most reliable bit location in the respective polar code.

Some of the method, first wireless devices, and non-transitory computer-readable medium described herein, may further include operations, features, means, or instructions for outputting, to a second wireless device, control information including an indication of the subcode mapping scheme.

Some examples of the method, first wireless devices, and non-transitory computer-readable medium described herein may further include operations, features, means, or instructions for obtaining, from a second wireless device, control information including an indication of the subcode mapping scheme.

In some examples of the method, first wireless devices, and non-transitory computer-readable medium described herein, the set of multiple error probability metrics includes a respective minimum distance metric for each of the set of multiple subcodes.

In some examples of the method, first wireless devices, and non-transitory computer-readable medium described herein, the set of multiple error probability metrics includes a respective weight metric for each of the set of multiple subcodes.

In some examples of the method, first wireless devices, and non-transitory computer-readable medium described herein, the set of multiple error probability metrics includes a respective probability of bit error or block error in an additive white gaussian noise (AWGN) channel.

In some examples of the method, first wireless devices, and non-transitory computer-readable medium described herein, the set of multiple communication probability metrics includes a respective communication likelihood for a message corresponding to each of the set of multiple message bit combinations.

In some examples of the method, first wireless devices, and non-transitory computer-readable medium described herein, each of the set of multiple subcodes includes a Reed Muller error correcting subcode.

Some examples of the method, first wireless devices, and non-transitory computer-readable medium described herein may further include operations, features, means, or instructions for monitoring for a set of messages to be transmitted by a second wireless device, where the first set of bits includes feedback bits that may be indicative of whether the first wireless device successfully decoded each message of the set of messages.

A method by a first wireless device is described. The method may include obtaining a message including an encoded first set of bits that are encoded using a first subcode of a set of multiple subcodes and decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

A first wireless device is described. The first wireless device may include one or more memories storing processor executable code, and one or more processors coupled with the one or more memories. The one or more processors may individually or collectively be operable to execute the code to cause the first wireless device to obtain a message including an encoded first set of bits that are encoded using a first subcode of a set of multiple subcodes and decode the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

Another first wireless device is described. The first wireless device may include means for obtaining a message including an encoded first set of bits that are encoded using a first subcode of a set of multiple subcodes and means for decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

A non-transitory computer-readable medium storing code is described. The code may include instructions executable by one or more processors to obtain a message including an encoded first set of bits that are encoded using a first subcode of a set of multiple subcodes and decode the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

In some examples of the method, first wireless devices, and non-transitory computer-readable medium described herein, the subcode mapping scheme indicates a set of multiple indexes, a first index of the set of multiple indexes maps the first set of bits to the first message bit combination, and the set of multiple indexes may be based on an ordering of the set of multiple communication probability metrics for the set of multiple message bit combinations.

### BRIEF DESCRIPTION OF THE DRAWINGS

FIG. 1 shows an example of a wireless communications system that supports remapping of messages to codewords for nonuniform message transmission in accordance with one or more aspects of the present disclosure.

FIG. 2 shows an example of a wireless communications system that supports remapping of messages to codewords for nonuniform message transmission in accordance with one or more aspects of the present disclosure.

FIG. 3 shows an example of a graph that supports remapping of messages to codewords for nonuniform message transmission in accordance with one or more aspects of the present disclosure.

FIG. 4 shows an example of a process flow that supports remapping of messages to codewords for nonuniform message transmission in accordance with one or more aspects of the present disclosure.

FIGS. 5 and 6 show block diagrams of devices that support remapping of messages to codewords for nonuniform message transmission in accordance with one or more aspects of the present disclosure.

FIG. 7 shows a block diagram of a communications manager that supports remapping of messages to codewords for nonuniform message transmission in accordance with one or more aspects of the present disclosure.

FIG. 8 shows a diagram of a system including a device that supports remapping of messages to codewords for nonuniform message transmission in accordance with one or more aspects of the present disclosure.

FIGS. 9 through 14 show flowcharts illustrating methods that support remapping of messages to codewords for nonuniform message transmission in accordance with one or more aspects of the present disclosure.

### DETAILED DESCRIPTION

In some wireless communications systems, a first device may use linear codes (e.g., Reed Muller codes, polar codes, or modified Reed Muller codes) to generate an encoded message for communication with a second device based on an input message. The linear codes may include one or more subcodes, with varying minimum distances. Subcodes with a larger minimum distance may be associated with a lower error probability, while subcodes with a smaller minimum distance may be associated with a higher error probability. The linear codes may map input messages to encoded messages associated with a subcode. In some cases, the first device may transmit a message using an arbitrarily mapped subcode (e.g., a mapping not based on communication probability metrics). However, in some communications between the first device and the second device, some messages may have a higher probability of being transmitted. If the first device uses an arbitrary mapping between messages and subcodes, the message with the highest probability of being transmitted may be mapped to the subcode with the highest error probability. The arbitrary mapping may increase the number of errors in communication between the first and second device, thereby negatively impacting communication reliability and efficiency.

According to techniques described herein, the first device may map messages to virtual messages such that the message with the message with the highest probability of being transmitted may be mapped to the virtual message associated with the subcode with the lowest error probability. In some cases, the second device may configure a mapping scheme for the mapping between messages and virtual messages at the first device via signaling. In accordance with one or more example mapping schemes, the subcodes are arranged in order from the subcode with the lowest error probability (e.g., the subcode with the largest minimum distance) to the subcode with the highest error probability (e.g., the sub code with the smallest minimum distance), the first device may be configured to map all possible messages (e.g., all 2K possible messages for a K-bit message) such that the message with the highest probability of being transmitted is encoded with a subcode with the lowest error probability. The subcode mapping scheme may be used for all possible messages of a particular bit length (e.g., quantity of bits). The subcode ordering may be dependent on bit significance ordering of the messages (e.g., most significant bit (MSB) to least significant bit (LSB) or LSB to MSB). Similar techniques may be used for modified Reed Muller codes and polar codes. The subcode mapping scheme may result in reduced error rates and retransmissions due to the increased utilization of subcodes with lower error probabilities. As a result, the overall throughput and reliability of wireless communications may be improved. These and other techniques are described in further detail with respect to the figures.

Aspects of the disclosure are initially described in the context of wireless communications systems. Additional aspects of the disclosure are described in the context of graphs and process flows. Aspects of the disclosure are further illustrated by and described herein with reference to apparatus diagrams, system diagrams, and flowcharts that relate to remapping of messages to codewords for nonuniform message transmission.

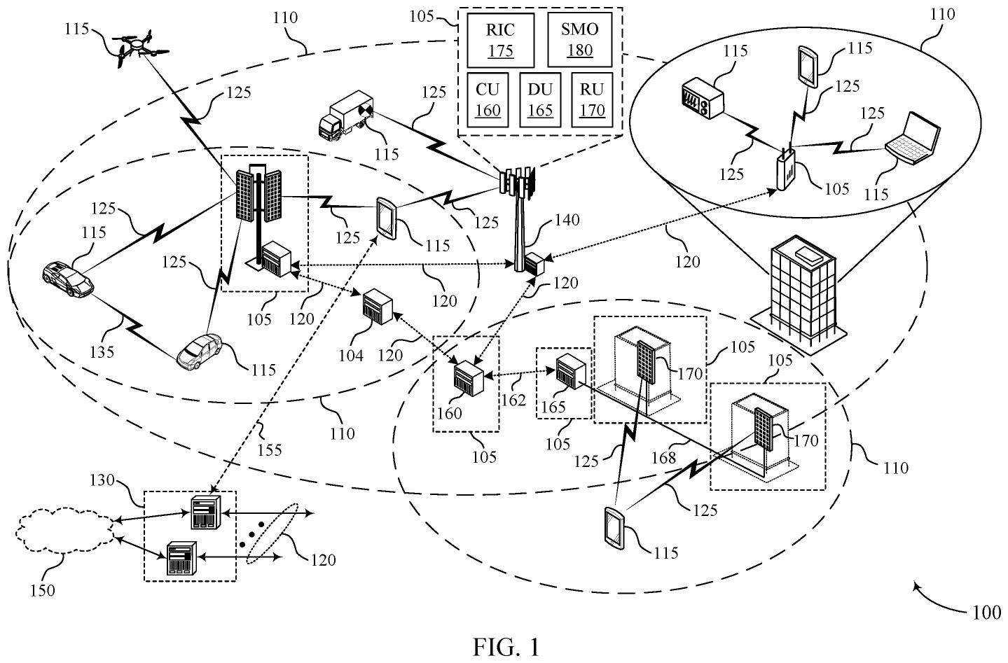

FIG. 1 shows an example of a wireless communications system 100 that supports remapping of messages to codewords for nonuniform message transmission in accordance with one or more aspects of the present disclosure. The wireless communications system 100 may include one or more devices, such as one or more network devices (e.g., network entities 105), one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via communication link(s) 125 (e.g., a radio frequency (RF) access link). For example, a network entity 105 may support a coverage area 110 (e.g., a geographic coverage area) over which the UEs 115 and the network entity 105 may establish the communication link(s) 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices in the wireless communications system 100 (e.g., other wireless communication devices, including UEs 115 or network entities 105), as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with a core network 130, or with one another, or both. For example, network entities 105 may communicate with the core network 130 via backhaul communication link(s) 120 (e.g., in accordance with an S1, N2, N3, or other interface protocol). In some examples, network entities 105 may communicate with one another via backhaul communication link(s) 120 (e.g., in accordance with an X2, Xn, or other interface protocol) either directly (e.g., directly between network entities 105) or indirectly (e.g., via the core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication link(s) 120, midhaul communication links 162, or fronthaul communication links 168 may be or include one or more wired links (e.g., an electrical link, an optical fiber link) or one or more wireless links (e.g., a radio link, a wireless optical link), among other examples or various combinations thereof. A UE 115 may communicate with the core network 130 via a communication link 155.

One or more of the network entities 105 or network equipment described herein may include or may be referred to as a base station 140 (e.g., a base transceiver station, a radio base station, an NR base station, an access point, a radio transceiver, a NodeB, an eNodeB (eNB), a next-generation NodeB or giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within one network entity (e.g., a network entity 105 or a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among multiple network entities (e.g., network entities 105), such as an integrated access and backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU), such as a CU 160, a distributed unit (DU), such as a DU 165, a radio unit (RU), such as an RU 170, a RAN Intelligent Controller (RIC), such as an RIC 175 (e.g., a Near-Real Time RIC (Near-RT RIC), a Non-Real Time RIC (Non-RT RIC)), a Service Management and Orchestration (SMO) system, such as an SMO system 180, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more of the network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, or any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 (e.g., one or more CUs) may be connected to a DU 165 (e.g., one or more DUs) or an RU 170 (e.g., one or more RUs), or some combination thereof, and the DUs 165, RUs 170, or both may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or multiple different RUs, such as an RU 170). In some cases, a functional split between a CU 160 and a DU 165 or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to a DU 165 via a midhaul communication link 162 (e.g., F1, F1-c, F1-u), and a DU 165 may be connected to an RU 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities (e.g., one or more of the network entities 105) that are in communication via such communication links.

In some wireless communications systems (e.g., the wireless communications system 100), infrastructure and spectral resources for radio access may support wireless backhaul link capabilities to supplement wired backhaul connections, providing an IAB network architecture (e.g., to a core network 130). In some cases, in an IAB network, one or more of the network entities 105 (e.g., network entities 105 or IAB node(s) 104) may be partially controlled by each other. The IAB node(s) 104 may be referred to as a donor entity or an IAB donor. A DU 165 or an RU 170 may be partially controlled by a CU 160 associated with a network entity 105 or base station 140 (such as a donor network entity or a donor base station). The one or more donor entities (e.g., IAB donors) may be in communication with one or more additional devices (e.g., IAB node(s) 104) via supported access and backhaul links (e.g., backhaul communication link(s) 120). IAB node(s) 104 may include an IAB mobile termination (IAB-MT) controlled (e.g., scheduled) by one or more DUs (e.g., DUs 165) of a coupled IAB donor. An IAB-MT may be equipped with an independent set of antennas for relay of communications with UEs 115 or may share the same antennas (e.g., of an RU 170) of IAB node(s) 104 used for access via the DU 165 of the IAB node(s) 104 (e.g., referred to as virtual IAB-MT (vIAB-MT)). In some examples, the IAB node(s) 104 may include one or more DUs (e.g., DUs 165) that support communication links with additional entities (e.g., IAB node(s) 104, UEs 115) within the relay chain or configuration of the access network (e.g., downstream). In such cases, one or more components of the disaggregated RAN architecture (e.g., the IAB node(s) 104 or components of the IAB node(s) 104) may be configured to operate according to the techniques described herein.

In the case of the techniques described herein applied in the context of a disaggregated RAN architecture, one or more components of the disaggregated RAN architecture may be configured to support test as described herein. For example, some operations described as being performed by a UE 115 or a network entity 105 (e.g., a base station 140) may additionally, or alternatively, be performed by one or more components of the disaggregated RAN architecture (e.g., components such as an IAB node, a DU 165, a CU 160, an RU 170, an RIC 175, an SMO system 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, vehicles, or meters, among other examples.

The UEs 115 described herein may be able to communicate with various types of devices, such as UEs 115 that may sometimes operate as relays, as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via the communication link(s) 125 (e.g., one or more access links) using resources associated with one or more carriers. The term “carrier” may refer to a set of RF spectrum resources having a defined PHY layer structure for supporting the communication link(s) 125. For example, a carrier used for the communication link(s) 125 may include a portion of an RF spectrum band (e.g., a bandwidth part (BWP)) that is operated according to one or more PHY layer channels for a given RAT (e.g., LTE, LTE-A, LTE-A Pro, NR). Each PHY layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities, such as one or more of the network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Ts=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems, such as the wireless communications system 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (STTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to UEs 115 (e.g., one or more UEs) or may include UE-specific search space sets for sending control information to a UE 115 (e.g., a specific UE).

In some examples, a network entity 105 (e.g., a base station 140, an RU 170) may be movable and therefore provide communication coverage for a moving coverage area, such as the coverage area 110. In some examples, coverage areas 110 (e.g., different coverage areas) associated with different technologies may overlap, but the coverage areas 110 (e.g., different coverage areas) may be supported by the same network entity (e.g., a network entity 105). In some other examples, overlapping coverage areas, such as a coverage area 110, associated with different technologies may be supported by different network entities (e.g., the network entities 105). The wireless communications system 100 may include, for example, a heterogeneous network in which different types of the network entities 105 support communications for coverage areas 110 (e.g., different coverage areas) using the same or different RATs.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs (e.g., one or more of the UEs 115) via a device-to-device (D2D) communication link, such as a D2D communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1: M) system in which each UE 115 transmits to one or more of the UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than one hundred kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) RAT, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The UEs 115 and the network entities 105 may support retransmissions of data to increase the likelihood that data is received successfully. Hybrid automatic repeat request (HARQ) feedback is one technique for increasing the likelihood that data is received correctly via a communication link (e.g., the communication link(s) 125, a D2D communication link 135). HARQ may include a combination of error detection (e.g., using a cyclic redundancy check (CRC)), forward error correction (FEC), and retransmission (e.g., automatic repeat request (ARQ)). HARQ may improve throughput at the MAC layer in relatively poor radio conditions (e.g., low signal-to-noise conditions). In some examples, a device may support same-slot HARQ feedback, in which case the device may provide HARQ feedback in a specific slot for data received via a previous symbol in the slot. In some other examples, the device may provide HARQ feedback in a subsequent slot, or according to some other time interval.

The devices (e.g., the UEs 115 and the network entities 105) may utilize encoding to improve communication reliability and efficiency. In some cases, a subcode (from a plurality of subcodes) is selected for encoding a message for communication by a transmitting device (e.g., UE 115 or network entity 105) to a receiving device, and different subcodes may be associated with different error probabilities. For example, Reed Muller subcodes may have different minimum distances, and a greater minimum distance may be associated with lower error probability at the receiver device for decoding a message. However, dependent on the communication scenario, some messages may have a higher likelihood of being transmitted, and if messages are mapped to subcodes arbitrarily, more likely messages may be encoded with subcodes with a higher error probability, which may result in communication inefficiencies and unreliability.

According to techniques described herein, a first device (e.g., UE 115) may map messages to virtual messages such that the message with the highest probability of being transmitted may be mapped to the virtual message associated with the subcode with the lowest error probability. In some cases, the second device (e.g., network entity 105) may configure the mapping between messages and virtual messages at the first device via signaling. For example, the subcodes are arranged in order from the subcode with the lowest error probability (e.g., the subcode with the largest minimum distance) to the subcode with the highest error probability (e.g., the sub code with the smallest minimum distance) and the possible message are arranged from a message bit combination with a highest probability of being transmitted to a lowest probability of being transmitted such that all possible messages (e.g., all 2^{K} possible messages for a K-bit message) are mapped to a subcode. This mapping scheme may result in the message with the highest probability of being transmitted being encoded with a subcode with the lowest error probability. The subcode ordering may be dependent on bit significance ordering of the messages (e.g., MSB to LSB or LSB to MSB). Similar techniques may be used for modified Reed Muller codes and polar codes. The subcode mapping scheme may result in reduced error rates and retransmissions due to the increased utilization of subcodes with lower error probabilities.

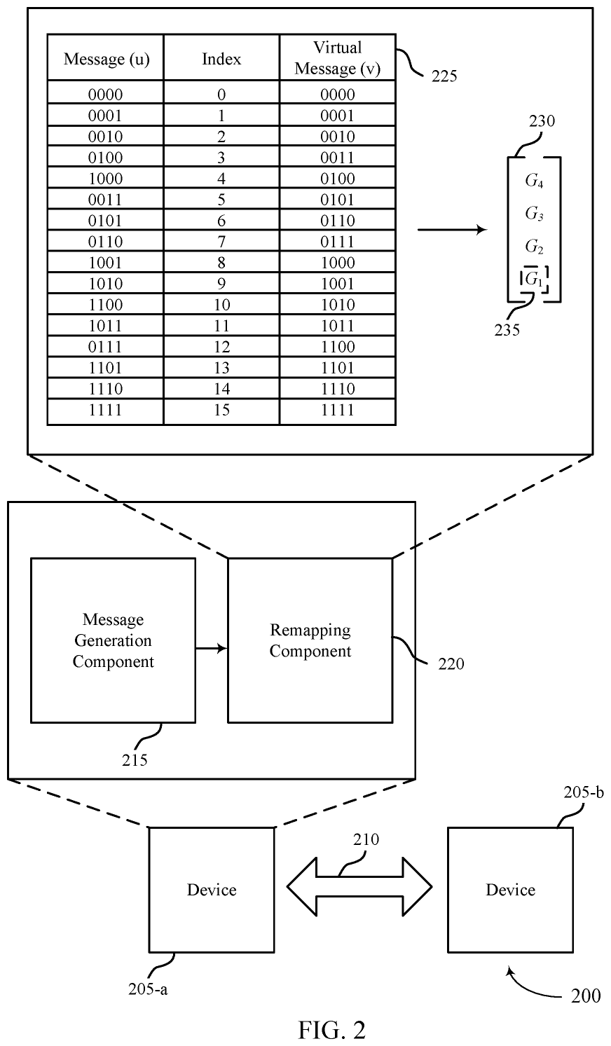

FIG. 2 shows an example of a wireless communications system 200 that supports remapping of messages to codewords for nonuniform message transmission in accordance with one or more aspects of the present disclosure. In some examples, wireless communications system 200 may implement aspects of wireless communications system 100. In some examples, a first device 205-a may communicate with a second device 205-b via communications link 210. The device 205 may represent an example of a UEs, such as the UEs 115 described herein with reference to FIG. 1, a network entity, such as the network entities 105 as described herein with reference to FIG. 1, or some other type of wireless devices. The devices 205 may include a message generation component 215 and a remapping component 220, which may be implemented in hardware, software, or both.

The first device 205-a may use linear codes 230 (e.g., generator matrix G) to generate an encoded message for communication with the second device 205-b based on an input message. The encoded message may be used for error detection and correction. For example, the message generation component 215 coupled with the first device 205-a may generate a K-bit input message (e.g., where K>0). The linear codes 230 may be used to generate the encoded message for a K-bit. In some cases, the first device 205-a may generate or transmit a nonuniform probability of messages. For example, the first device may generate or transmit K-bit messages where some messages of the 2^{K} possible messages have a higher probability of being transmitted compared to other messages of the 2^{K} possible messages (e.g., the 2^{K} possible messages may be associated with some communication probability metrics).

For example, the first device may transmit hybrid automatic repeat request (HARQ) feedback. A nonuniform probability of messages may appear in HARQ feedback communication scenarios. The first device 205-a may transmit an acknowledgment (ACK) or a negative acknowledgment (NACK), where an ACK (e.g., bit 0) may be more likely than NACK (e.g., bit 1). In other words, the first device 205-a may indicate an acknowledgment of a received message by setting a corresponding feedback bit to 0 (e.g., ACK), and the first device 205-a may indicate an error in receiving or decoding a message by setting a corresponding feedback bit to 1 (e.g., NACK). In some cases, the first device 205-a may be more likely to transmit an ACK compared to a NACK. For example, at a 10% block error rate (BLER) in PDSCH (e.g., 10% of code blocks associated with PDSCH transmissions may contain errors) may correspond to a 10% NACK probability and a 90% ACK probability. In other words, the first device 205-a may transmit approximately 10% 1-bits and 90% 0-bits based on the BLER of 10%. In HARQ feedback communications, the second device may schedule one or more messages (e.g., downlink messages) and the first device may transmit HARQ feedback for the one or more messages. For example, the second device may schedule four downlink transmissions (e.g., PDSCH). The first device may send a 4-bit message for HARQ ACK/NACK (e.g., HARQ feedback) based on the decoding of the downlink transmissions. For example, if the first device successfully decodes all four downlink transmissions, the first device may generate a 4-bit message including “0000”.

The first device 205-a may utilize linear codes 230 (e.g., a generator matrix, Reed Muller codes, polar codes, or modified Reed Muller codes) to generate encoded messages based on an input message. In other words, the input messages may be associated with subcodes in the linear codes 230. The linear codes 230 (e.g., Reed Muller codes) may include subcodes with larger minimum distances (e.g., 0-th order Reed Muller code and 1st order Reed Muller code) relative to other Reed Muller subcodes (e.g., nth order Reed Muller codes). For example, the linear codes 230 may be a Reed Muller codes including a 0-th order Reed Muller code (e.g., [G1] 0th order Reed Muller code), a 1st order Reed Muller code (e.g., [G1, G2] 1st order Reed Muller code), etc. In other words, the linear codes 230 may include one or more subcodes with varying minimum distances. Subcodes with a larger minimum distance may be associated with a lower error probability (e.g., a lower error probability metric), while subcodes with a smaller minimum distance may be associated with a higher error probability (e.g., a higher error probability metric). In some cases, an order of the subcode may correspond to the minimum distance of the subcode. For example, a subcode with a relatively high order may correspond with a smaller minimum distance while a subcode with a relatively low order may correspond with a larger minimum distance. For example, the linear codes 230 may include a first subcode (e.g., a 0-th order Reed Muller code) associated with a relatively low minimum distance and a second subcode (e.g., a 3rd order Reed Muller code) associated with a relatively high minimum distance.

In some cases, the first device 205-a may transmit a message using an arbitrary mapping between input messages and subcodes. For example, the arbitrary mapping may map a message for HARQ feedback including “1111” to the subcode with the largest minimum distance and lowest error probability. The probability of the message “1111” given a BLER of 10% may be 0.01%. Additionally, a message for HARQ feedback including “0000” may be mapped to the subcode with the smallest minimum distance and highest error probability. The probability of the message “0000” given a BLER of 10% may be 65.61%. In other words, using the arbitrary mapping, 65.61% of all transmitted four bit HARQ feedback messages may be transmitted using the subcode with the highest error probability while only 0.01% of all four bit HARQ feedback messages may be transmitted using the subcode with the lowest error probability given a BLER of 10%. The arbitrary mapping may cause increased error based on the overuse of subcodes with smaller minimum distances and higher error probabilities.

According to techniques described herein, the first device 205-a may map messages with a higher probability of being transmitted to subcodes with a lower probability for error and map messages with a lower probability of being transmitted to subcodes with a higher probability of error. For example, the first device 205-a may map a more likely message (e.g., a message with higher probability metrics) to a subcode with a larger minimum distance and map a less likely message (e.g., a message with a lower probability metric relative to the first message) to a subcode with a smaller minimum distance. The first and second subcode may be of the same linear codes 230. To achieve the mapping using a mapping scheme, the first device may map all possible messages (e.g., all 2^{K} possible messages for a K-bit message, u) to virtual messages (e.g., sets of codeword bits, v), which may be examples of a binary version of indexes as described herein in further detail herein. The first device 205-a may be configured or defined with a one-to-one mapping (e.g., u→v), and apply the linear encoder on the virtual message (e.g., x=v*G). The one-to-one mapping and linear encoder may be an example of a subcode mapping scheme. For example, table 225 may represent a possible mapping for all possible 4-bit messages (e.g., message bit combinations). The one-to-one mapping may reorder the messages (e.g., possible message bit combinations) such that the message with the highest probability of being transmitted may be mapped to virtual message corresponding to the subcode with the largest minimum distance and lowest error probability. The first device may use linear codes 230 (e.g., G) where the minimum distance decreases from the last layer (e.g., row 235) up.

For example, the first device 205-a may compute (or receive an indication of) the probability of each message (e.g., u) and then reorder the messages according to the probability from the highest probability to the lowest probability. The first device 205-a may reorder the messages (e.g., possible message bit combinations) for HARQ feedback given a 10% BLER, as shown in table 225. In the table 225, the message bit combinations (e.g., messages (u)) containing more 0 bits may have a higher probability of being transmitted and may be mapped to virtual messages corresponding to subcodes with larger minimum distances. The first device 205-a may map the messages to the index that corresponds to the message in the sorted list. For example, the first device 205-a may map the message including “0011” to index 5 based on the message including “0011” having the sixth highest probability of being transmitted. The first device 205-a may use the binary representation of the index as the message after the mapping (e.g., v). The first device 205-a may map the message including “0011” to a virtual message including “0101” based on the message including “0011” being mapped to index 5. The first device may encode the virtual message including “0101” using linear codes 230 and transmit the encoded message to the second device 205-b via communications link 210. The second device 205-b may receive the transmission from the first device 205-a and decode the transmission using linear codes 230. The second device may decode the encoded message associated with the virtual message including “0101.” The second device may map the virtual message including “0101” to the message “0011” in accordance with table 225. The mapping of messages to virtual messages may be preconfigured at the first device 205-a or indicated by the second device 205-b. Additionally, or alternatively, the first device may transmit an indication of the mapping to the second device 205-b.

The subcode mapping scheme may order the rows 235 for linear codes 230 such that the best subcode (e.g., the subcode with the largest minimum distance) corresponds to the LSB of the virtual message (e.g., v). The table 225 may represent reordered messages where the probability of a 0-bit is larger than the probability of a 1-bit for a 4-bit message, where the subcode with the largest minimum distance corresponds to the LSB of the virtual message. The MSB of the remapped messages (e.g., virtual messages, v) correspond to the worst subcode (e.g., the subcode with the smallest minimum distance) and the LSB of the remapped messages correspond to the best subcode (e.g., the subcode with the best, or largest, minimum distance). In some cases, the LSB of the virtual message may be to the right (e.g., the binary representation of index 1 may be computed as “0001”). The first device 205-a may reorder the rows of the generator matrix G (e.g., linear codes 230) of the Reed Muller codes such that the rows 235 with a largest weight are placed at the bottom (e.g., correspond to the LSB of the virtual message). The weights of the rows 235 may increase or decrease sequentially or according to some predefined configuration. For example, the weights for the rows 235 in the table 225 may be configured as, weight (G1)>weight (G2)>weight (G3)>weight (G4). The row G4 may be placed at the bottom of the generator matrix G based on the LSB of the virtual messages being on the right.

Alternatively, the first device 205-a may order the messages according to the probability from the lowest probability to the highest probability and order the rows 235 of linear codes 230 such that the best subcode (e.g., in terms of error probability) corresponds to the MSB of the virtual message. In some other cases, the first device 205-a may compute the binary representation of the index with reverse LSB through MSB ordering (e.g., index 1 has a binary representation of “1000” instead of “0001”). The rows 235 of linear codes 230 may be ordered so that larger weight rows 235 are placed at the top of the generator matrix G. The order of the rows 235 may be preconfigured at the first device 205-a and the second device 205-b. Additionally, or alternatively, the second device 205-b may indicate an ordering of the rows 235.

The linear codes 230 may also be an example of polar codes. The first device 205-a may reorder (e.g., the map) from the u domain to the v domain. The first device may map the MSB of the new message (e.g., the virtual message in the v domain) to the least reliable location of the polar codes. The first device may map the LSB of the new message to the more reliable locations of the polar codes. In other words, the messages may be mapped via virtual messages such that the message with the highest probability of being transmitted is mapped to the most reliable location of polar codes and the message with the lowest probability of being transmitted is mapped to the least reliable location of polar codes. If the message includes CRC, the CRC may be included at the end of the message (e.g., the most reliable location). Alternatively, the first device 205-a may map the MSB to indices with larger weights and the LSB to indices with smaller weights (e.g., treat polar codes as Reed Muller codes).

The linear codes 230 may include k rows 235. The generator matrix (e.g., linear codes 230) may be ordered such that the first device may select the best k′<k rows 235 (e.g., the k′ rows corresponding to the subcodes with the largest minimum distance) as the subcode used to transmit a k′-bit message (e.g., the first device may use k′ rows 235 of the k rows 235 for a generator matrix). In other words, the first device may select k′ largest weight rows 235 from the k total rows 235. The order of the rows 235 of linear codes 230 may be such that the subcode with the largest minimum distance corresponds to the MSB of the virtual message.

Additionally, or alternatively, the first device 205-a may map messages to virtual messages based on a priority associated with the message. For example, the first device 205-a may map. The messages may be ordered from highest priority to lowest priority such that that the message with the highest priority may be mapped to a virtual message associated with a subcode with the largest minimum distance (e.g., lowest error probability) and the message with the lowest priority may be mapped to a virtual message associated with a subcode with the smallest error priority.

As described herein, various different subcode mapping schemes may be used to map possible message bit combinations (e.g., messages) to subcodes. That is, a first mapping scheme may order the possible message bit combinations based on the likelihood of being transmitted and order the subcodes based on the error probability metrics and use an index so that a least significant bit of the lowest index is applicable to the subcode with the lowest error probability metric. A second mapping scheme map reverse the bit ordering such that the least significant bit is first in the index (e.g., for example 1 in a binary representation is 1000 instead of 0001) and such that the subcodes with larger weights are places at the top. A third mapping scheme may map subcodes to the NR modified Reed Muller code (e.g., as listed in NR standards). A fourth mapping scheme may map message bit combinations (e.g., messages) to polar code based on the bit location reliability. Additionally, control signaling may be used to indicate the mapping scheme to use, and in some cases, the control signaling may indicate that one of a set of configured mapping scheme is to be activated for some communications.

As an example, utilization of the mapping scheme described herein, the message generation component 215 of the first device 205-a generates the set of bits for the message. For example, the message generation component 215 may generate the message as a four bit HARQ feedback message. The remapping component, which may be an example of an encoder, may obtain the four bit message and identify a message bit combination in the subcode mapping scheme (e.g., in the messages (u)) that corresponds (e.g., has the same values as) the obtained message. The remapping component 220 may then identify the corresponding index as the virtual message and encode the virtual message using the mapped subcode. As a result, the subcode that is used to encode the message is mapped to a message bit combination corresponding to the original message. The encoded message is transmitted to the second device 205-b, which may be decode the message as described herein. Similar techniques may be used to encode/decode messages (e.g., based on possible message bit combinations and mapped subcodes) using the various mapping schemes described herein.

As a result of these subcode mapping schemes the first device 205-a and the second device 205-b may have improved communication reliability, improved coordination between devices, and improved usage of communications resources. That is, by mapping possible message bit combinations based on communication likelihood to subcodes based on error probability, the more likely messages may have an improved communication reliability, thereby improving the overall reliability and efficiency of the wireless communications system 200.

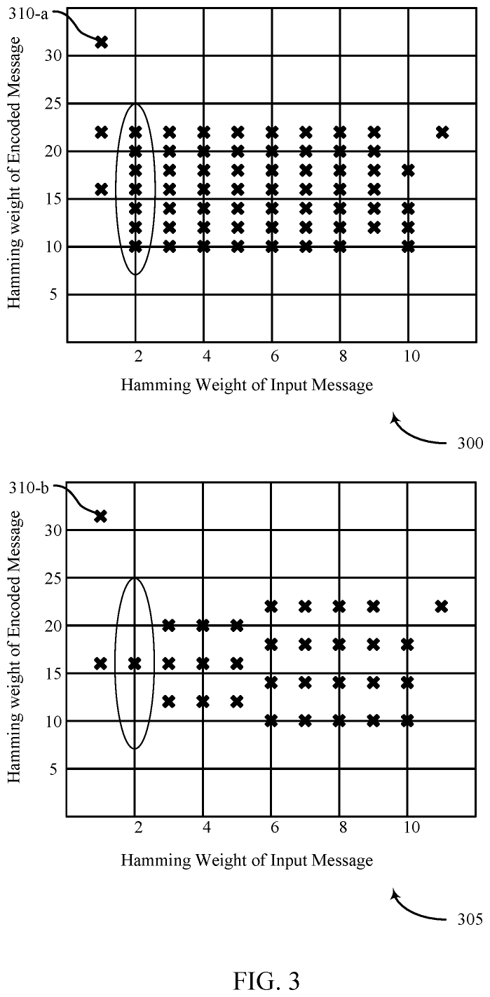

FIG. 3 shows an example of a graph 300 and a graph 305 that support remapping of messages to codewords for nonuniform message transmission in accordance with one or more aspects of the present disclosure. The graph 300 and the graph 305 may be examples of the relationship between an input hamming weight associated with an input message and a hamming weight associated with an encoded message. For example, the x-axis may represent the hamming weight of an input message (e.g., an original message). The y-axis may represent the hamming weight of an encoded message generated using an input message associated with the input hamming weight. For example, a device (e.g., the first device 205-a or the second device 205-b with reference to FIG. 2) may generate an encoded message using an input message via a generator matrix, as described herein in greater detail with reference to FIG. 2. The minimum distance for a given hamming weight of an input message may be the smallest hamming weight of an encoded message generated from an input message of the given hamming weight. The hamming weight may represent the number of 1-bits in the message. The datapoints 310 (e.g., datapoint 310-a and datapoint 310-b) may represent one or more input messages associated with the same hamming weight corresponding to one or more encoded messages with the same hamming weight.

For example, graph 300 may represent a modified Reed Muller code (e.g., modified code ordering based on NR standards) using an arbitrary mapping between input messages and subcodes. The minimum distance for an input message with a hamming weight of two (e.g., an input message with two 1-bits) may be ten as illustrated in graph 300. In another example, graph 305 may represent a modified Reed Muller code using a mapping based on communication probability metric (e.g., mapping more likely input messages to virtual messages associated with subcodes corresponding to a larger minimum distance as described herein in greater detail with reference to FIG. 2). The rows of the modified Reed Muller code may be ordered such that the best subcode corresponds to the MSB of the virtual message (e.g., LSB-to-MSB input message ordering). The minimum distance of an input message with a hamming weight of two may be 16 as illustrated in graph 305. The larger minimum distance associated with the graph 305 may provide for higher communications reliability.

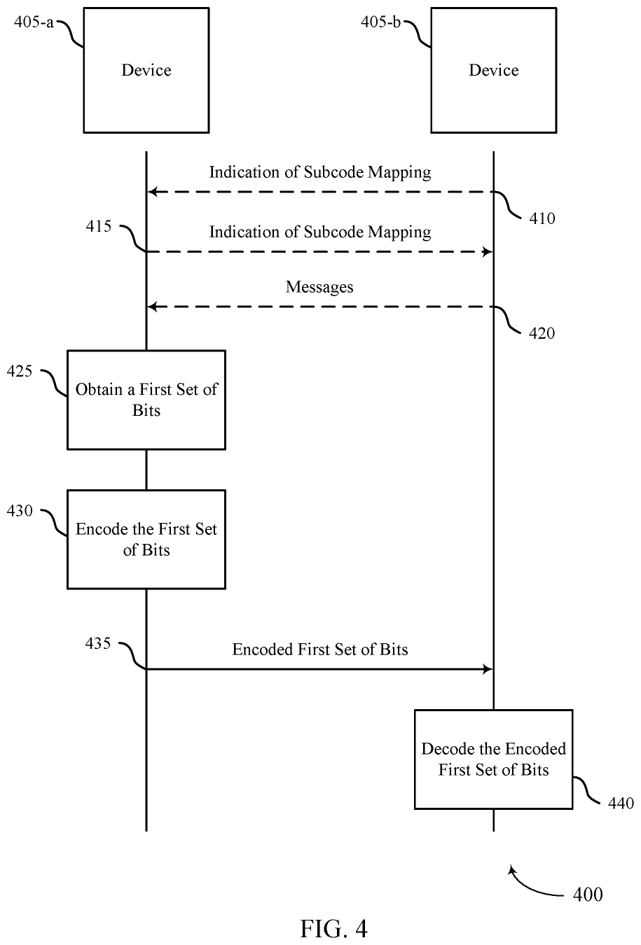

FIG. 4 shows an example of a process flow 400 that supports remapping of messages to codewords for nonuniform message transmission in accordance with one or more aspects of the present disclosure. In some examples, process flow 400 may implement aspects of, or be implemented by aspects of, the wireless communications system 100, the wireless communications system 200, and the graph 300. In some examples, a first device 405-a may communicate with a second device 405-b. The device 205 may represent an example of a UEs, such as the UEs 115 described herein with reference to FIG. 1, a network entity, such as the network entities 105 as described herein with reference to FIG. 1, or some other type of wireless devices.

At 410, the first device 405-a may obtain, from a second device 405-b, control information including an indication of the subcode mapping scheme. For example, the control information may be received via control signaling (e.g., RRC, medium access control layer control element (MAC-CE), and/or other control information signaling) and may indicate the subcode mapping scheme. The control information may indicate that the subcode mapping scheme is to be used (e.g., the subcode mapping scheme is activated), or the control information may be indicative of the mapping of subcodes to message bit combinations. In some cases, the subcode mapping is in the form of table that maps message bit combinations, indexes (e.g., virtual messages), and subcodes. In some cases, the first device 405-a may be configured with (e.g., via control signaling) a set of subcode mapping schemes and the obtained control information may indicate or activate one of the configured subcode mapping schemes to use for communications with the second device 405-b.

At 415, the first device 405-a may output, to a second device 405-b, control information including an indication of the subcode mapping scheme. The control information may be signaled via control signaling. The control information may indicate that the subcode mapping scheme is to be used (e.g., the subcode mapping scheme is activated), or the control information may be indicative of the mapping of subcodes to message bit combinations. In some cases, the subcode mapping is in the form of table that maps message bit combinations, indexes, and subcodes. As described herein, the second device 405-b may be configured with (e.g., via control signaling) a set of subcode mapping schemes and the obtained control information may indicate or activate one of the configured subcode mapping schemes to use for communications with the first device 405-a.

At 420, the second device 405-b may output, and the first device 405-a may monitor for, a set of messages. In cases where the second device 405-b is a network entity and the first device 405-a is a UE, the set of messages may be physical downlink shared channel (PDSCH) messages. Alternatively, if the first device is a network entity and the second device 405-b is a UE, the set of messages may be physical uplink shared channel (PUSCH) messages. In some cases, both the first device and the second devices are UEs, and the set of messages are physical sidelink shared channel (PSSCH) messages.

At 425, the first device 405-a may obtain a first message bit combination that includes a first quantity of bits for inclusion in a message to be transmitted by the first wireless device. In some cases, the first set of bits may include feedback bits that are indicative of whether the first wireless device successfully decoded each message of the set of messages. Thus, to obtain the first set of bits, the first device 405-a may generate the feedback bits based on monitoring for the set messages.

At 430, the first device 405-a may encode the first set of bits using a first subcode that is mapped to the first message bit combination of a set of message bit combinations in accordance with a subcode mapping scheme. The first message bit combination may be the message bit combination that corresponds to the set of bits that is obtained (e.g., generated by the first device 405-a). For example, an encoder may receive the first set of bits from another component or layer in the first device, and the encoder may identify the corresponding message bit combination (e.g., with the same set of bits), the corresponding index, and then use the subcode that is mapped to the index as described herein. Each of the set of message bit combinations may have the first quantity of bits. The subcode mapping scheme may be based on a set of communication probability metrics for the set of message bit combinations and a set of error probability metrics for a set of subcodes that includes the first subcode.

The first subcode mapping scheme may indicate a set of indexes, wherein a first index of the set of indexes maps the first set of bits to the first message bit combination, and wherein the set of indexes are based on an ordering of the set of communication probability metrics for the set of message bit combinations.

The subcode mapping scheme may map the set of message bit combinations ordered in accordance with first sequential order of a respective communication probability metric for each of the set of message bit combinations, to the set of subcodes ordered in accordance with a second sequential order of a respective error probability metric for each of the set of subcodes. The second sequential order may be reverse of the first sequential order. That is, the first sequential order of message bit combinations may be from lowest to highest communication probability metric, and the second sequential order of subcodes may be from highest to lowest error probability metric.

The subcode mapping scheme may map one or more first message bit combinations, with higher communication probability metrics than one or more second message bit combinations, to one or more first subcodes with lower error probability metrics than one or more second subcodes, and the one or more second message bit combinations, with lower communication probability metrics than the one or more first message bit combinations, to the one or more second subcodes with higher error probability metrics than the one or more first subcodes.

The subcode mapping scheme may map the set of message bit combinations ordered sequentially, using a respective communication probability metric for each of the set of message bit combinations, to a set of sequential indexes, and each index of the set of sequential indexes to a respective subcode of the set of subcodes ordered sequentially using a respective error probability metric.

The set of subcodes may be ordered such that a subcode with a lowest error probability metric among the set of subcodes is mapped to a lowest index of the set of sequential indexes resulting in a LSB of the lowest index being applicable to the subcode with the lowest error probability metric.

In some cases, the set of message bit combinations may be ordered sequentially from a highest communication probability metric to a lowest communication probability metric, each respective set of bits for each index of the set of sequential indexes are ordered from a LSB to a MSB such that a first bit position in each respective set of bits is the LSB and a last bit position in each respective set of bits is the MSB, and the set of subcodes are ordered from a highest error probability metric to a lowest error probability metric.

In some cases, the set of message bit combinations may be ordered sequentially from a highest communication probability metric to a lowest communication probability metric, each respective set of bits for each index of the set of sequential indexes are ordered from a LSB to a MSB such that a first bit position in each respective set of bits is the LSB and a last bit position in each respective set of bits is the MSB, and the set of subcodes are ordered from a lowest error probability metric to a highest error probability metric.

In some cases, the set of message bit combinations are ordered sequentially from a highest communication probability to a lowest communication probability, each respective set of bits for each index of the set of sequential indexes are ordered from a LSB to a MSB such that a first bit position in each respective set of bits is the least significant bit and a last bit position in each respective set of bits is the most significant bit, and wherein the set of subcodes are included in a generator matrix with a modified Reed Muller code ordering.

Each respective set of bits for each index of the plurality of sequential indexes are ordered from a MSB to a LSB and the subcode mapping scheme may map a MSB of each index of the set of sequential indexes to a first bit location with lower reliability than a second bit location in each subcode of the set of subcodes, and a LSB of each index of the set of sequential indexes to the second bit location with a higher reliability than the first bit location, where each subcode is a respective polar code, where the subcode mapping scheme results in a respective MSB of each index may be mapped to a least reliable bit location in a respective polar code and a respective LSB of each index being mapped to a respective most reliable bit location in the respective polar code.

Each respective set of bits for each index of the plurality of sequential indexes are ordered from a LSB to a MSB and the subcode mapping scheme may map a MSB of each index of the set of sequential indexes to a first bit location with lower reliability than a second bit location in each subcode of the set of subcodes, and a LSB of each index of the set of sequential indexes to the second bit location with a higher reliability than the first bit location, where each subcode is a respective polar code, where the subcode mapping scheme results in a respective MSB of each index may be mapped to a least reliable bit location in a respective polar code and a respective LSB of each index being mapped to a respective most reliable bit location in the respective polar code. In some cases, the subcode mapping scheme may map a cyclic redundancy check bit to a respective most reliable location in each polar code of the set of subcodes.

In some cases, the set of error probability metrics may include a respective minimum distance metric for each of the set of subcodes. The set of error probability metrics may include a respective weight metric for each of the set of subcodes. The set of communication probability metrics may include a respective communication likelihood for a message corresponding to each of the set of message bit combinations. Each of the set of subcodes may include a Reed Muller error correcting subcode.

In some cases, the set of error probability metrics comprises a respective probability of bit error or block error in an additive white gaussian noise (AWGN) channel.

At 435, the first device 405-a may output the message including the encoded first set of bits. The message including the encoded first set of bits may be transmitted via one or more physical channels, via control signaling, or a combination thereof.

At 440, the second device 405-b may decode the encoded first set of bits using the first subcode that is mapped to a first message bit combination of a set of message bit combinations in accordance with a subcode mapping scheme. Each of the set of message bit combinations may have a first quantity of bits. The subcode mapping scheme may be based on a set of communication probability metrics for the set of message bit combinations and a set of error probability metrics for the set of subcodes that includes the first subcode. In some cases, the second device 405-b may attempt to decode the received message using subcodes until the message is successfully decoded. Additionally, or alternatively, the subcode that is used to encode the message may be signaled to the second device 405-b.

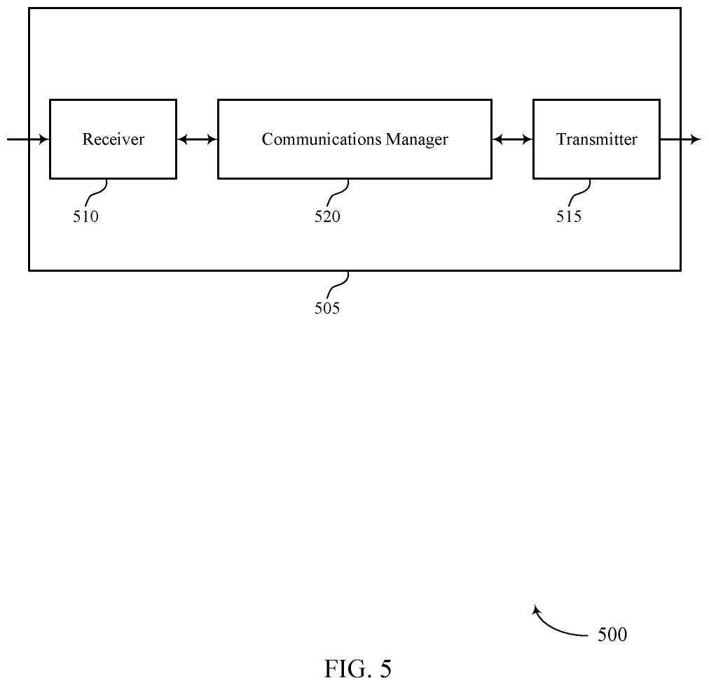

FIG. 5 shows a block diagram 500 of a device 505 that supports remapping of messages to codewords for nonuniform message transmission in accordance with one or more aspects of the present disclosure. The device 505 may be an example of aspects of a wireless device as described herein. The device 505 may include a receiver 510, a transmitter 515, and a communications manager 520. The device 505, or one or more components of the device 505 (e.g., the receiver 510, the transmitter 515, the communications manager 520), may include at least one processor, which may be coupled with at least one memory, to, individually or collectively, support or enable the described techniques. Each of these components may be in communication with one another (e.g., via one or more buses).

The receiver 510 may provide a means for receiving information such as packets, user data, control information, or any combination thereof associated with various information channels (e.g., control channels, data channels, information channels related to remapping of messages to codewords for nonuniform message transmission). Information may be passed on to other components of the device 505. The receiver 510 may utilize a single antenna or a set of multiple antennas.

The transmitter 515 may provide a means for transmitting signals generated by other components of the device 505. For example, the transmitter 515 may transmit information such as packets, user data, control information, or any combination thereof associated with various information channels (e.g., control channels, data channels, information channels related to remapping of messages to codewords for nonuniform message transmission). In some examples, the transmitter 515 may be co-located with a receiver 510 in a transceiver module. The transmitter 515 may utilize a single antenna or a set of multiple antennas.

The communications manager 520, the receiver 510, the transmitter 515, or various combinations or components thereof may be examples of means for performing various aspects of remapping of messages to codewords for nonuniform message transmission as described herein. For example, the communications manager 520, the receiver 510, the transmitter 515, or various combinations or components thereof may be capable of performing one or more of the functions described herein.

In some examples, the communications manager 520, the receiver 510, the transmitter 515, or various combinations or components thereof may be implemented in hardware (e.g., in communications management circuitry). The hardware may include at least one of a processor, a DSP, a CPU, an ASIC, an FPGA or other programmable logic device, a microcontroller, discrete gate or transistor logic, discrete hardware components, or any combination thereof configured as or otherwise supporting, individually or collectively, a means for performing the functions described in the present disclosure. In some examples, at least one processor and at least one memory coupled with the at least one processor may be configured to perform one or more of the functions described herein (e.g., by one or more processors, individually or collectively, executing instructions stored in the at least one memory).

Additionally, or alternatively, the communications manager 520, the receiver 510, the transmitter 515, or various combinations or components thereof may be implemented in code (e.g., as communications management software or firmware) executed by at least one processor (e.g., referred to as a processor-executable code). If implemented in code executed by at least one processor, the functions of the communications manager 520, the receiver 510, the transmitter 515, or various combinations or components thereof may be performed by a general-purpose processor, a DSP, a CPU, an ASIC, an FPGA, a microcontroller, or any combination of these or other programmable logic devices (e.g., configured as or otherwise supporting, individually or collectively, a means for performing the functions described in the present disclosure).

In some examples, the communications manager 520 may be configured to perform various operations (e.g., receiving, obtaining, monitoring, outputting, transmitting) using or otherwise in cooperation with the receiver 510, the transmitter 515, or both. For example, the communications manager 520 may receive information from the receiver 510, send information to the transmitter 515, or be integrated in combination with the receiver 510, the transmitter 515, or both to obtain information, output information, or perform various other operations as described herein.

The communications manager 520 may support wireless communications in accordance with examples as disclosed herein. For example, the communications manager 520 is capable of, configured to, or operable to support a means for obtaining a first message bit combination that includes a first quantity of bits for inclusion in a message to be transmitted by the first wireless device. The communications manager 520 is capable of, configured to, or operable to support a means for encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode. The communications manager 520 is capable of, configured to, or operable to support a means for outputting the message including the encoded first set of bits.

Additionally, or alternatively, the communications manager 520 may support wireless communications in accordance with examples as disclosed herein. For example, the communications manager 520 is capable of, configured to, or operable to support a means for obtaining a message including an encoded first set of bits that are encoded using a first subcode of a set of multiple subcodes. The communications manager 520 is capable of, configured to, or operable to support a means for decoding the encoded first set of bits using the first subcode that is mapped to the first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

By including or configuring the communications manager 520 in accordance with examples as described herein, the device 505 (e.g., at least one processor controlling or otherwise coupled with the receiver 510, the transmitter 515, the communications manager 520, or a combination thereof) may support techniques for reduced power consumption, more efficient utilization of communication resources, and the like.

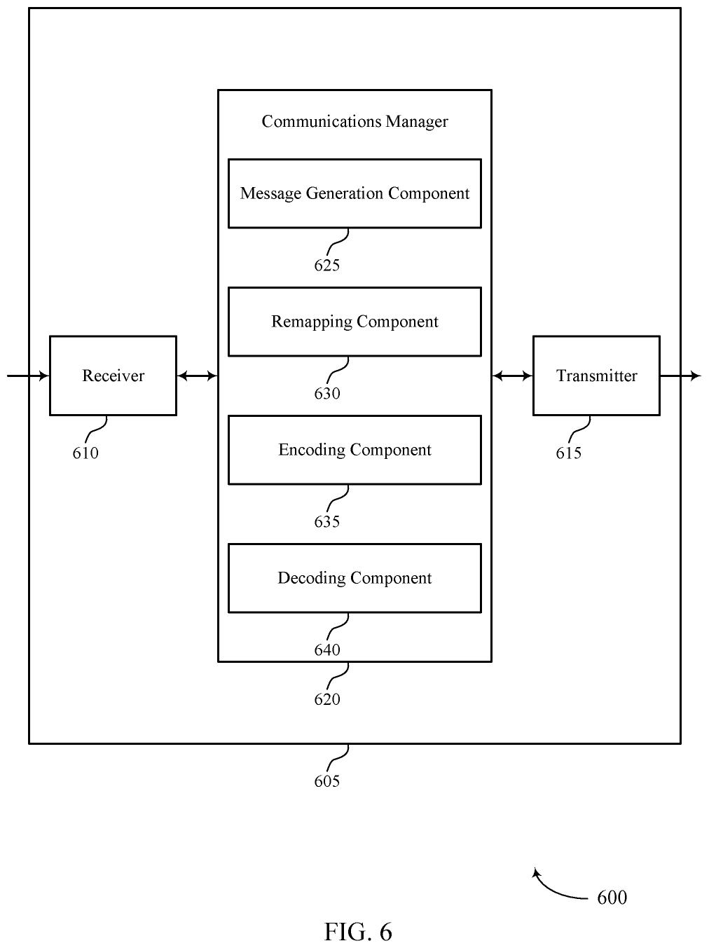

FIG. 6 shows a block diagram 600 of a device 605 that supports remapping of messages to codewords for nonuniform message transmission in accordance with one or more aspects of the present disclosure. The device 605 may be an example of aspects of a device 505 or a wireless device (e.g., UE 115 or network entity 105) as described herein. The device 605 may include a receiver 610, a transmitter 615, and a communications manager 620. The device 605, or one or more components of the device 605 (e.g., the receiver 610, the transmitter 615, the communications manager 620), may include at least one processor (not shown), which may be coupled with at least one memory (not shown), to support the described techniques. Each of these components may be in communication with one another (e.g., via one or more buses).

The receiver 610 may provide a means for receiving information such as packets, user data, control information, or any combination thereof associated with various information channels (e.g., control channels, data channels, information channels related to remapping of messages to codewords for nonuniform message transmission). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to remapping of messages to codewords for nonuniform message transmission). In some examples, the transmitter 615 may be co-located with a receiver 610 in a transceiver module. The transmitter 615 may utilize a single antenna or a set of multiple antennas.

The device 605, or various components thereof, may be an example of means for performing various aspects of remapping of messages to codewords for nonuniform message transmission as described herein. For example, the communications manager 620 may include a message generation component 625, a remapping component 630, an encoding component 635, a decoding component 640, or any combination thereof. The communications manager 620 may be an example of aspects of a communications manager 520 as described herein. In some examples, the communications manager 620, or various components thereof, may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications in accordance with examples as disclosed herein. The message generation component 625 is capable of, configured to, or operable to support a means for obtaining a first message bit combination that includes a first quantity of bits for inclusion in a message to be transmitted by the first wireless device. The remapping component 630 is capable of, configured to, or operable to support a means for encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode. The encoding component 635 is capable of, configured to, or operable to support a means for outputting the message including the encoded first set of bits.

Additionally, or alternatively, the communications manager 620 may support wireless communications in accordance with examples as disclosed herein. The decoding component 640 is capable of, configured to, or operable to support a means for obtaining a message including an encoded first set of bits that are encoded using a first subcode of a set of multiple subcodes. The decoding component 640 is capable of, configured to, or operable to support a means for decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

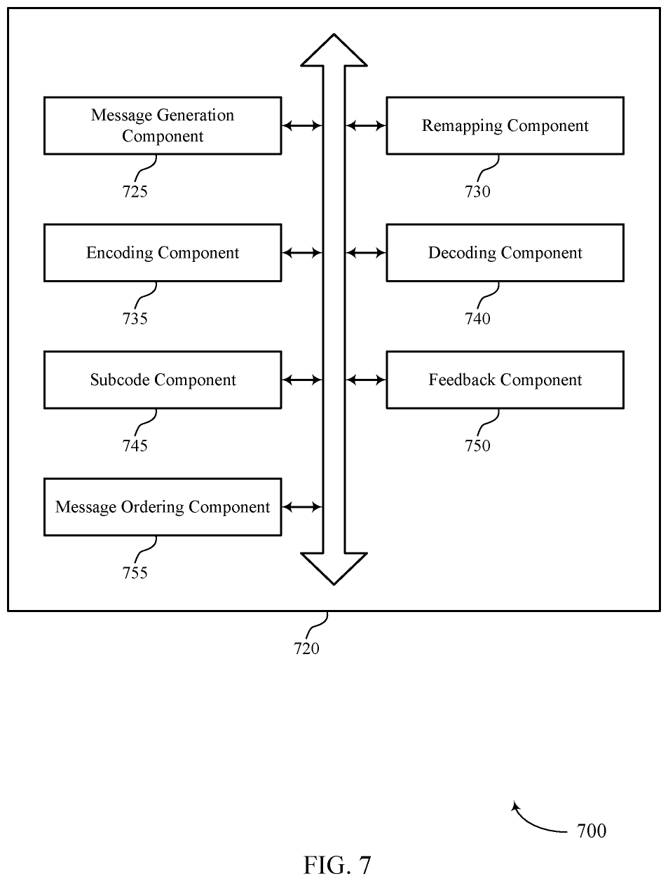

FIG. 7 shows a block diagram 700 of a communications manager 720 that supports remapping of messages to codewords for nonuniform message transmission in accordance with one or more aspects of the present disclosure. The communications manager 720 may be an example of aspects of a communications manager 520, a communications manager 620, or both, as described herein. The communications manager 720, or various components thereof, may be an example of means for performing various aspects of remapping of messages to codewords for nonuniform message transmission as described herein. For example, the communications manager 720 may include a message generation component 725, a remapping component 730, an encoding component 735, a decoding component 740, a subcode component 745, a feedback component 750, a message ordering component 755, or any combination thereof. Each of these components, or components or subcomponents thereof (e.g., one or more processors, one or more memories), may communicate, directly or indirectly, with one another (e.g., via one or more buses).

The communications manager 720 may support wireless communications in accordance with examples as disclosed herein. The message generation component 725 is capable of, configured to, or operable to support a means for obtaining a first message bit combination that includes a first quantity of bits for inclusion in a message to be transmitted by the first wireless device. The remapping component 730 is capable of, configured to, or operable to support a means for encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode. The encoding component 735 is capable of, configured to, or operable to support a means for outputting the message including the encoded first set of bits.

In some examples, the subcode mapping scheme indicates a set of multiple indexes. In some examples, a first index of the set of multiple indexes maps the first set of bits to the first message bit combination. In some examples, the set of multiple indexes are based on an ordering of the set of multiple communication probability metrics for the set of multiple message bit combinations.

In some examples, the set of multiple message bit combinations ordered in accordance with first sequential order of a respective communication probability metric for each of the set of multiple message bit combinations may be mapped to the set of multiple subcodes ordered in accordance with a second sequential order of a respective error probability metric for each of the set of multiple subcodes, where the second sequential order is reverse of the first sequential order.

In some examples, the subcode mapping scheme maps one or more first message bit combinations, with higher communication probability metrics than one or more second message bit combinations, to one or more first subcodes with lower error probability metrics than one or more second subcodes. In some examples, the subcode mapping scheme maps, the one or more second message bit combinations, with lower communication probability metrics than the one or more first message bit combinations, to the one or more second subcodes with higher error probability metrics than the one or more first subcodes.

In some examples, the subcode mapping scheme maps the set of multiple message bit combinations ordered sequentially, using a respective communication probability metric for each of the set of multiple message bit combinations, to a set of multiple sequential indexes. In some examples, the subcode mapping scheme maps each index of the set of multiple sequential indexes to a respective subcode of the set of multiple subcodes ordered sequentially using a respective error probability metric.

In some examples, the set of multiple subcodes are ordered such that a subcode with a lowest error probability metric among the set of multiple subcodes is mapped to a lowest index of the set of multiple sequential indexes resulting in a LSB of the lowest index being applicable to the subcode with the lowest error probability metric.

In some examples, in accordance with the subcode mappings scheme, the multiple message bit combinations are ordered sequentially from a highest communication probability metric to a lowest communication probability metric, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are ordered from a highest error probability metric to a lowest error probability metric.

In some examples, in accordance with the subcode mappings scheme, the multiple message bit combinations are ordered sequentially from a highest communication probability metric to a lowest communication probability metric, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are ordered from a lowest error probability metric to a highest error probability metric.

In some examples, in accordance with the subcode mappings scheme, the multiple message bit combinations are ordered sequentially from a highest communication probability to a lowest communication probability, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are included in a generator matrix with a modified Reed Muller code ordering.

In some examples, each respective set of bits for each index of the plurality of sequential indexes are ordered from a MSB to a LSB and the subcode mapping scheme maps a MSB of each index of the set of multiple sequential indexes to a first bit location with lower reliability than a second bit location in each subcode of the set of multiple subcodes. In some examples, the subcode mapping scheme maps a LSB of each index of the set of multiple sequential indexes to the second bit location with a higher reliability than the first bit location, where each subcode is a respective polar code, where the subcode mapping scheme results in a respective most significant bit of each index being mapped to a least reliable bit location in a respective polar code and a respective least significant bit of each index being mapped to a respective most reliable bit location in the respective polar code.

In some examples, each respective set of bits for each index of the plurality of sequential indexes are ordered from a LSB to a MSB and the subcode mapping scheme maps a MSB of each index of the set of multiple sequential indexes to a first bit location with lower reliability than a second bit location in each subcode of the set of multiple subcodes. In some examples, the subcode mapping scheme maps a LSB of each index of the set of multiple sequential indexes to the second bit location with a higher reliability than the first bit location, where each subcode is a respective polar code, where the subcode mapping scheme results in a respective MSB of each index being mapped to a least reliable bit location in a respective polar code and a respective LSB of each index being mapped to a respective most reliable bit location in the respective polar code.

In some examples, the subcode mapping scheme maps a cyclic redundancy check bit to a respective most reliable location in each polar code of the set of multiple subcodes.

In some examples, the remapping component 730 is capable of, configured to, or operable to support a means for outputting, to a second wireless device, control information including an indication of the subcode mapping scheme.

In some examples, the remapping component 730 is capable of, configured to, or operable to support a means for obtaining, from a second wireless device, control information including an indication of the subcode mapping scheme.

In some examples, the set of multiple error probability metrics includes a respective minimum distance metric for each of the set of multiple subcodes.

In some examples, the set of multiple error probability metrics includes a respective probability of bit error or block error in an AWGN channel.

In some examples, the set of multiple error probability metrics includes a respective weight metric for each of the set of multiple subcodes.

In some examples, the set of multiple communication probability metrics includes a respective communication likelihood for a message corresponding to each of the set of multiple message bit combinations.

In some examples, each of the set of multiple subcodes includes a Reed Muller error correcting subcode.

In some examples, the feedback component 750 is capable of, configured to, or operable to support a means for monitoring for a set of messages to be transmitted by a second wireless device, where the first set of bits includes feedback bits that are indicative of whether the first wireless device successfully decoded each message of the set of messages.

Additionally, or alternatively, the communications manager 720 may support wireless communications in accordance with examples as disclosed herein. The decoding component 740 is capable of, configured to, or operable to support a means for obtaining a message including an encoded first set of bits that are encoded using a first subcode of a set of multiple subcodes. In some examples, the decoding component 740 is capable of, configured to, or operable to support a means for decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

In some examples, the subcode mapping scheme indicates a set of multiple indexes. In some examples, a first index of the set of multiple indexes maps the first set of bits to the first message bit combination. In some examples, the set of multiple indexes are based on an ordering of the set of multiple communication probability metrics for the set of multiple message bit combinations.

In some examples, the set of multiple message bit combinations ordered in accordance with first sequential order of a respective communication probability metric for each of the set of multiple message bit combinations may be mapped to the set of multiple subcodes ordered in accordance with a second sequential order of a respective error probability metric for each of the set of multiple subcodes, where the second sequential order is reverse of the first sequential order.

In some examples, the subcode mapping scheme maps one or more first message bit combinations, with higher communication probability metrics than one or more second message bit combinations, to one or more first subcodes with lower error probability metrics than one or more second subcodes. In some examples, the subcode mapping scheme maps the one or more second message bit combinations, with lower communication probability metrics than the one or more first message bit combinations, to the one or more second subcodes with higher error probability metrics than the one or more first subcodes.

In some examples, the subcode mapping scheme maps the set of multiple message bit combinations ordered sequentially, using a respective communication probability metric for each of the set of multiple message bit combinations, to a set of multiple sequential indexes. In some examples, the subcode mapping scheme maps each index of the set of multiple sequential indexes to a respective subcode of the set of multiple subcodes ordered sequentially using a respective error probability metric.

In some examples, the set of multiple subcodes are ordered such that a subcode with a lowest error probability metric among the set of multiple subcodes is mapped to a lowest index of the set of multiple sequential indexes resulting in a LSB of the lowest index being applicable to the subcode with the lowest error probability metric.

In some examples, in accordance with the subcode mapping scheme, the plurality of message bit combinations are ordered sequentially from a highest communication probability metric to a lowest communication probability metric, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are ordered from a highest error probability metric to a lowest error probability metric.

In some examples, in accordance with the subcode mapping scheme, the plurality of message bit combinations are ordered sequentially from a highest communication probability metric to a lowest communication probability metric, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are ordered from a lowest error probability metric to a highest error probability metric.

In some examples, in accordance with the subcode mapping scheme, the multiple message bit combinations are ordered sequentially from a highest communication probability to a lowest communication probability, each respective set of bits for each index of the set of multiple sequential indexes are ordered from a LSB to a MSB such that a first bit position in each respective set of bits is the least significant bit and a last bit position in each respective set of bits is the most significant bit, and the set of multiple subcodes are included in a generator matrix with a modified Reed Muller code ordering.

In some examples, each respective set of bits for each index of the set of multiple sequential indexes are ordered from a MSB to a LSB and the subcode mapping scheme maps a MSB of each index of the set of multiple sequential indexes to a first bit location with lower reliability than a second bit location in each subcode of the set of multiple subcodes. In some examples, the subcode mapping scheme maps a LSB of each index of the set of multiple sequential indexes to the second bit location with a higher reliability than the first bit location, where each subcode is a respective polar code, where the subcode mapping scheme results in a respective MSB of each index being mapped to a least reliable bit location in a respective polar code and a respective LSB of each index being mapped to a respective most reliable bit location in the respective polar code.

In some examples, each respective set of bits for each index of the set of multiple sequential indexes are ordered from a LSB to a MSB and the subcode mapping scheme maps a MSB of each index of the set of multiple sequential indexes to a first bit location with lower reliability than a second bit location in each subcode of the set of multiple subcodes. In some examples, the subcode mapping scheme maps a LSB of each index of the set of multiple sequential indexes to the second bit location with a higher reliability than the first bit location, where each subcode is a respective polar code, where the subcode mapping scheme results in a respective MSB of each index being mapped to a least reliable bit location in a respective polar code and a respective LSB of each index being mapped to a respective most reliable bit location in the respective polar code.

In some examples, the subcode mapping scheme maps a cyclic redundancy check bit to a respective most reliable location in each polar code of the set of multiple subcodes.

In some examples, the remapping component 730 is capable of, configured to, or operable to support a means for outputting, to a second wireless device, control information including an indication of the subcode mapping scheme.

In some examples, the remapping component 730 is capable of, configured to, or operable to support a means for obtaining, from a second wireless device, control information including an indication of the subcode mapping scheme.

In some examples, the set of multiple error probability metrics includes a respective minimum distance metric for each of the set of multiple subcodes.

In some examples, the set of multiple error probability metrics includes a respective weight metric for each of the set of multiple subcodes.

In some examples, the set of multiple error probability metrics includes a respective probability of bit error or block error in an AWGN channel.

In some examples, the set of multiple communication probability metrics includes a respective communication likelihood for a message corresponding to each of the set of multiple message bit combinations.

In some examples, each of the set of multiple subcodes includes a Reed Muller error correcting subcode.

In some examples, the feedback component 750 is capable of, configured to, or operable to support a means for outputting, to a second wireless device, a set of messages, where the first set of bits includes feedback bits that are indicative of whether the second wireless device successfully decoded each message of the set of messages.

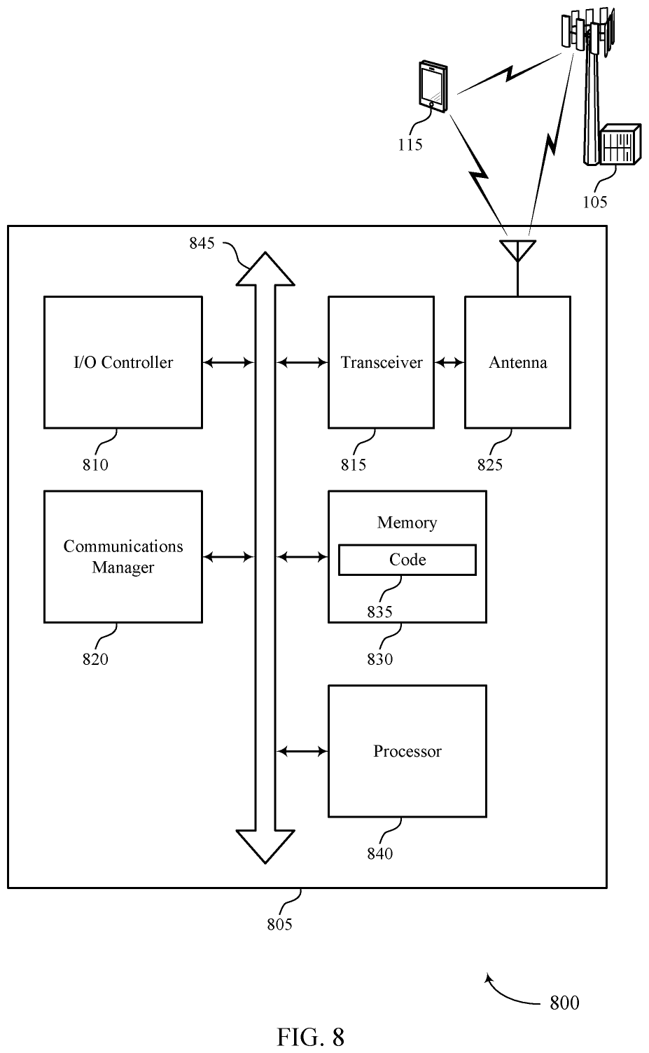

FIG. 8 shows a diagram of a system 800 including a device 805 that supports remapping of messages to codewords for nonuniform message transmission in accordance with one or more aspects of the present disclosure. The device 805 may be an example of or include components of a device 505, a device 605, or a wireless device as described herein. The device 805 may include components for bi-directional voice and data communications including components for transmitting and receiving communications, such as a communications manager 820, an I/O controller, such as an I/O controller 810, a transceiver 815, one or more antennas 825, at least one memory 830, code 835, and at least one processor 840. These components may be in electronic communication or otherwise coupled (e.g., operatively, communicatively, functionally, electronically, electrically) via one or more buses (e.g., a bus 845).

The I/O controller 810 may manage input and output signals for the device 805. The I/O controller 810 may also manage peripherals not integrated into the device 805. In some cases, the I/O controller 810 may represent a physical connection or port to an external peripheral. In some cases, the I/O controller 810 may utilize an operating system such as iOS®, ANDROID®, MS-DOS®, MS-WINDOWS®, OS/2®, UNIX®, LINUX®, or another known operating system. Additionally, or alternatively, the I/O controller 810 may represent or interact with a modem, a keyboard, a mouse, a touchscreen, or a similar device. In some cases, the I/O controller 810 may be implemented as part of one or more processors, such as the at least one processor 840. In some cases, a user may interact with the device 805 via the I/O controller 810 or via hardware components controlled by the I/O controller 810.

In some cases, the device 805 may include a single antenna. However, in some other cases, the device 805 may have more than one antenna, which may be capable of concurrently transmitting or receiving multiple wireless transmissions. The transceiver 815 may communicate bi-directionally via the one or more antennas 825 using wired or wireless links as described herein. For example, the transceiver 815 may represent a wireless transceiver and may communicate bi-directionally with another wireless transceiver. The transceiver 815 may also include a modem to modulate the packets, to provide the modulated packets to one or more antennas 825 for transmission, and to demodulate packets received from the one or more antennas 825. The transceiver 815, or the transceiver 815 and one or more antennas 825, may be an example of a transmitter 515, a transmitter 615, a receiver 510, a receiver 610, or any combination thereof or component thereof, as described herein.

The at least one memory 830 may include RAM and ROM. The at least one memory 830 may store computer-readable, computer-executable, or processor-executable code, such as the code 835. The code 835 may include instructions that, when executed by the at least one processor 840, cause the device 805 to perform various functions described herein. The code 835 may be stored in a non-transitory computer-readable medium such as system memory or another type of memory. In some cases, the code 835 may not be directly executable by the at least one processor 840 but may cause a computer (e.g., when compiled and executed) to perform functions described herein. In some cases, the at least one memory 830 may include, among other things, a BIOS which may control basic hardware or software operation such as the interaction with peripheral components or devices.

The at least one processor 840 may include one or more intelligent hardware devices (e.g., one or more general-purpose processors, one or more DSPs, one or more central processing units (CPUs), one or more graphics processing units (GPUs), one or more neural processing units (NPUs) (also referred to as neural network processors or deep learning processors (DLPs)), one or more microcontrollers, one or more ASICs, one or more FPGAs, one or more programmable logic devices, discrete gate or transistor logic, one or more discrete hardware components, or any combination thereof). In some cases, the at least one processor 840 may be configured to operate a memory array using a memory controller. In some other cases, a memory controller may be integrated into the at least one processor 840. The at least one processor 840 may be configured to execute computer-readable instructions stored in a memory (e.g., the at least one memory 830) to cause the device 805 to perform various functions (e.g., functions or tasks supporting remapping of messages to codewords for nonuniform message transmission). For example, the device 805 or a component of the device 805 may include at least one processor 840 and at least one memory 830 coupled with or to the at least one processor 840, the at least one processor 840 and the at least one memory 830 configured to perform various functions described herein. In some examples, the at least one processor 840 may include multiple processors and the at least one memory 830 may include multiple memories. One or more of the multiple processors may be coupled with one or more of the multiple memories, which may, individually or collectively, be configured to perform various functions described herein. In some examples, the at least one processor 840 may be a component of a processing system, which may refer to a system (such as a series) of machines, circuitry (including, for example, one or both of processor circuitry (which may include the at least one processor 840) and memory circuitry (which may include the at least one memory 830)), or components, that receives or obtains inputs and processes the inputs to produce, generate, or obtain a set of outputs. The processing system may be configured to perform one or more of the functions described herein. For example, the at least one processor 840 or a processing system including the at least one processor 840 may be configured to, configurable to, or operable to cause the device 805 to perform one or more of the functions described herein. Further, as described herein, being “configured to,” being “configurable to,” and being “operable to” may be used interchangeably and may be associated with a capability, when executing code 835 (e.g., processor-executable code) stored in the at least one memory 830 or otherwise, to perform one or more of the functions described herein.

The communications manager 820 may support wireless communications in accordance with examples as disclosed herein. For example, the communications manager 820 is capable of, configured to, or operable to support a means for obtaining a first message bit combination that includes a first quantity of bits for inclusion in a message to be transmitted by the first wireless device. The communications manager 820 is capable of, configured to, or operable to support a means for encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based on a set of multiple communication probability metrics for the set of multiple message bit combinations and a set of multiple error probability metrics for a set of multiple subcodes that includes the first subcode. The communications manager 820 is capable of, configured to, or operable to support a means for outputting the message including the encoded first set of bits.

Additionally, or alternatively, the communications manager 820 may support wireless communications in accordance with examples as disclosed herein. For example, the communications manager 820 is capable of, configured to, or operable to support a means for obtaining a message including an encoded first set of bits that are encoded using a first subcode of a set of multiple subcodes. The communications manager 820 is capable of, configured to, or operable to support a means for decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based on a set of multiple communication probability metrics for the set of multiple message bit combinations and a set of multiple error probability metrics for the set of multiple subcodes that includes the first subcode.

By including or configuring the communications manager 820 in accordance with examples as described herein, the device 805 may support techniques for improved communication reliability, reduced latency, reduced power consumption, more efficient utilization of communication resources, improved coordination between devices, and the like.

In some examples, the communications manager 820 may be configured to perform various operations (e.g., receiving, monitoring, transmitting) using or otherwise in cooperation with the transceiver 815, the one or more antennas 825, or any combination thereof. Although the communications manager 820 is illustrated as a separate component, in some examples, one or more functions described herein with reference to the communications manager 820 may be supported by or performed by the at least one processor 840, the at least one memory 830, the code 835, or any combination thereof. For example, the code 835 may include instructions executable by the at least one processor 840 to cause the device 805 to perform various aspects of remapping of messages to codewords for nonuniform message transmission as described herein, or the at least one processor 840 and the at least one memory 830 may be otherwise configured to, individually or collectively, perform or support such operations.

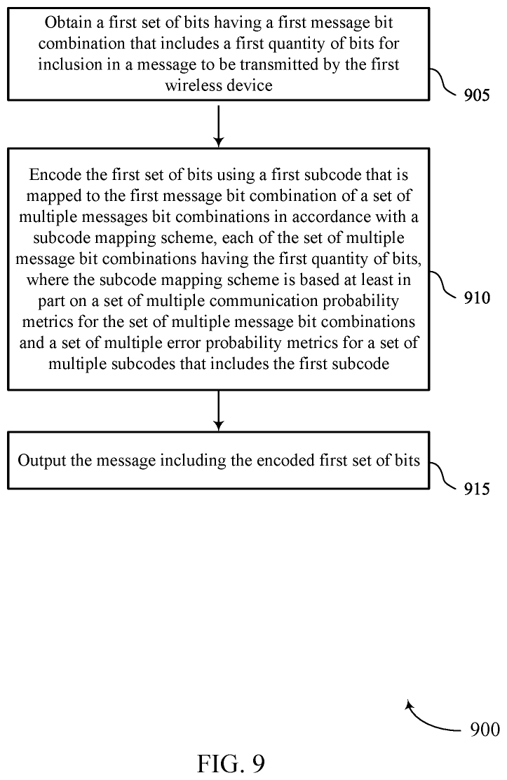

FIG. 9 shows a flowchart illustrating a method 900 that supports remapping of messages to codewords for nonuniform message transmission in accordance with one or more aspects of the present disclosure. The operations of the method 900 may be implemented by a wireless device or its components as described herein. For example, the operations of the method 900 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 905, the method may include obtaining a first message bit combination that includes a first quantity of bits for inclusion in a message to be transmitted by the first wireless device. The operations of 905 may be performed in accordance with examples as disclosed herein. In some examples, aspects of the operations of 905 may be performed by a message generation component 725 as described herein with reference to FIG. 7.

At 910, the method may include encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based at least in part on a set of multiple communication probability metrics for the set of multiple message bit combinations and a set of multiple error probability metrics for a set of multiple subcodes that includes the first subcode. The operations of 910 may be performed in accordance with examples as disclosed herein. In some examples, aspects of the operations of 910 may be performed by a remapping component 730 as described herein with reference to FIG. 7.

At 915, the method may include outputting the message including the encoded first set of bits. The operations of 915 may be performed in accordance with examples as disclosed herein. In some examples, aspects of the operations of 915 may be performed by an encoding component 735 as described herein with reference to FIG. 7.

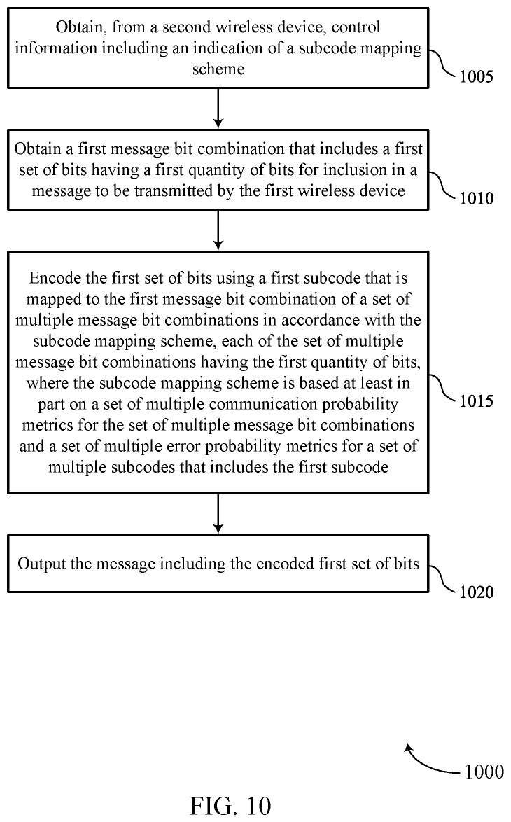

FIG. 10 shows a flowchart illustrating a method 1000 that supports remapping of messages to codewords for nonuniform message transmission in accordance with one or more aspects of the present disclosure. The operations of the method 1000 may be implemented by a wireless device or its components as described herein. For example, the operations of the method 1000 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 1005, the method may include obtaining, from a second wireless device, control information including an indication of a subcode mapping scheme. The operations of 1005 may be performed in accordance with examples as disclosed herein. In some examples, aspects of the operations of 1005 may be performed by a remapping component 730 as described herein with reference to FIG. 7.

At 1010, the method may include obtaining a first message bit combination that includes a first quantity of bits for inclusion in a message to be transmitted by the first wireless device. The operations of 1010 may be performed in accordance with examples as disclosed herein. In some examples, aspects of the operations of 1010 may be performed by a message generation component 725 as described herein with reference to FIG. 7.

At 1015, the method may include encoding the first set of bits using a first subcode that is mapped to the first message bit combination of a set of multiple message bit combinations in accordance with the subcode mapping scheme, each of the set of multiple message bit combinations having the first quantity of bits, where the subcode mapping scheme is based at least in part on a set of multiple communication probability metrics for the set of multiple message bit combinations and a set of multiple error probability metrics for a set of multiple subcodes that includes the first subcode. The operations of 1015 may be performed in accordance with examples as disclosed herein. In some examples, aspects of the operations of 1015 may be performed by a remapping component 730 as described herein with reference to FIG. 7.

At 1020, the method may include outputting the message including the encoded first set of bits. The operations of 1020 may be performed in accordance with examples as disclosed herein. In some examples, aspects of the operations of 1020 may be performed by an encoding component 735 as described herein with reference to FIG. 7.

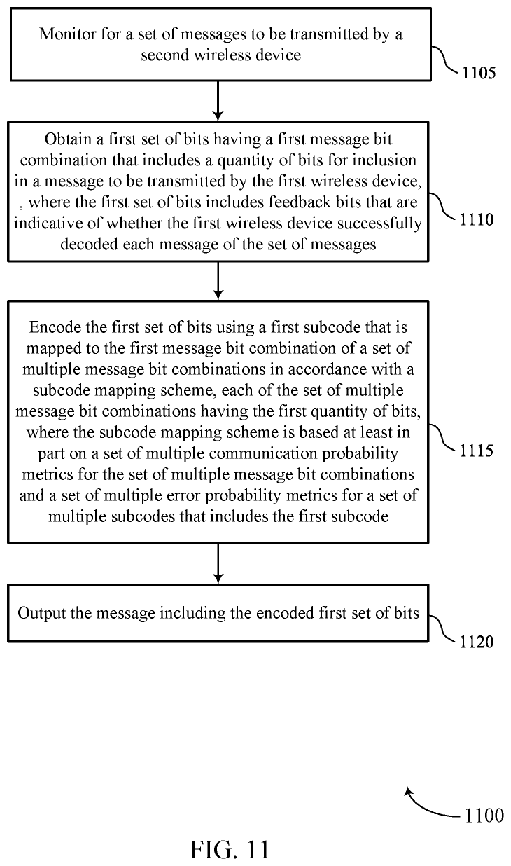

FIG. 11 shows a flowchart illustrating a method 1100 that supports remapping of messages to codewords for nonuniform message transmission in accordance with one or more aspects of the present disclosure. The operations of the method 1100 may be implemented by a wireless device or its components as described herein. For example, the operations of the method 1100 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 1105, the method may include monitoring for a set of messages to be transmitted by a second wireless device. The operations of 1120 may be performed in accordance with examples as disclosed herein. In some examples, aspects of the operations of 1120 may be performed by a feedback component 750 as described herein with reference to FIG. 7.

At 1110, the method may include obtaining a first message bit combination that includes a first quantity of bits for inclusion in a message to be transmitted by the first wireless device, where the first set of bits includes feedback bits that are indicative of whether the first wireless device successfully decoded each message of the set of messages. The operations of 1105 may be performed in accordance with examples as disclosed herein. In some examples, aspects of the operations of 1105 may be performed by a message generation component 725 as described herein with reference to FIG. 7.

At 1115, the method may include encoding the first set of bits using a first subcode that is mapped to the first message bit combination of a set of multiple message bit combinations in accordance with a subcode mapping scheme, each of the set of multiple message bit combinations having the first quantity of bits, where the subcode mapping scheme is based at least in part on a set of multiple communication probability metrics for the set of multiple message bit combinations and a set of multiple error probability metrics for a set of multiple subcodes that includes the first subcode. The operations of 1110 may be performed in accordance with examples as disclosed herein. In some examples, aspects of the operations of 1110 may be performed by a remapping component 730 as described herein with reference to FIG. 7.

At 1120, the method may include outputting the message including the encoded first set of bits. The operations of 1115 may be performed in accordance with examples as disclosed herein. In some examples, aspects of the operations of 1115 may be performed by an encoding component 735 as described herein with reference to FIG. 7.

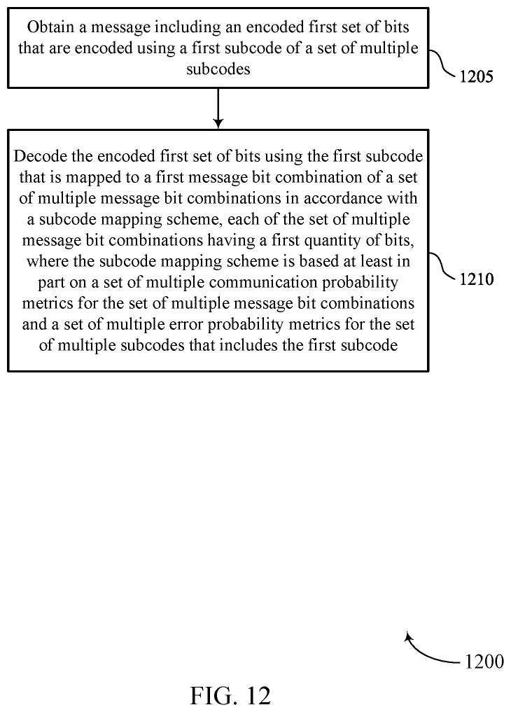

FIG. 12 shows a flowchart illustrating a method 1200 that supports remapping of messages to codewords for nonuniform message transmission in accordance with one or more aspects of the present disclosure. The operations of the method 1200 may be implemented by a wireless device or its components as described herein. For example, the operations of the method 1200 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 1205, the method may include obtaining a message including an encoded first set of bits that are encoded using a first subcode of a set of multiple subcodes. The operations of 1205 may be performed in accordance with examples as disclosed herein. In some examples, aspects of the operations of 1205 may be performed by a decoding component 740 as described herein with reference to FIG. 7.

At 1210, the method may include decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based at least in part on a set of multiple communication probability metrics for the set of multiple message bit combinations and a set of multiple error probability metrics for the set of multiple subcodes that includes the first subcode. The operations of 1210 may be performed in accordance with examples as disclosed herein. In some examples, aspects of the operations of 1210 may be performed by a decoding component 740 as described herein with reference to FIG. 7.

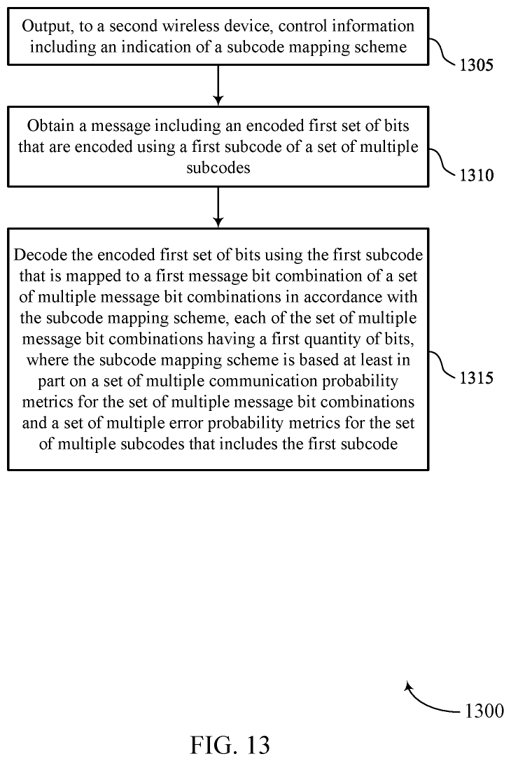

FIG. 13 shows a flowchart illustrating a method 1300 that supports remapping of messages to codewords for nonuniform message transmission in accordance with one or more aspects of the present disclosure. The operations of the method 1300 may be implemented by a wireless device or its components as described herein. For example, the operations of the method 1300 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 1305, the method may include outputting, to a second wireless device, control information including an indication of a subcode mapping scheme. The operations of 1305 may be performed in accordance with examples as disclosed herein. In some examples, aspects of the operations of 1305 may be performed by a remapping component 730 as described herein with reference to FIG. 7.

At 1310, the method may include obtaining a message including an encoded first set of bits that are encoded using a first subcode of a set of multiple subcodes. The operations of 1310 may be performed in accordance with examples as disclosed herein. In some examples, aspects of the operations of 1310 may be performed by a decoding component 740 as described herein with reference to FIG. 7.

At 1315, the method may include decoding the encoded first set of bits using the first subcode that is mapped to a first message bit combination of a set of multiple message bit combinations in accordance with the subcode mapping scheme, each of the set of multiple message bit combinations having a first quantity of bits, where the subcode mapping scheme is based at least in part on a set of multiple communication probability metrics for the set of multiple message bit combinations and a set of multiple error probability metrics for the set of multiple subcodes that includes the first subcode. The operations of 1315 may be performed in accordance with examples as disclosed herein. In some examples, aspects of the operations of 1315 may be performed by a decoding component 740 as described herein with reference to FIG. 7.

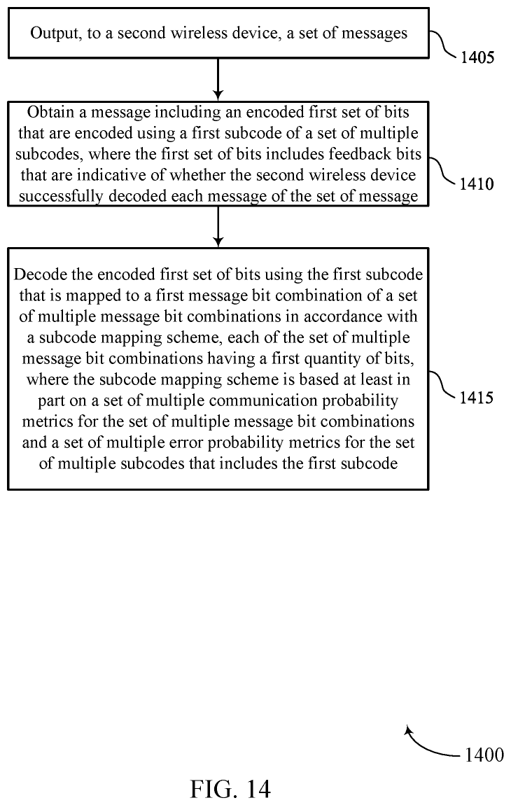

FIG. 14 shows a flowchart illustrating a method 1400 that supports remapping of messages to codewords for nonuniform message transmission in accordance with one or more aspects of the present disclosure. The operations of the method 1400 may be implemented by a wireless device or its components as described herein. For example, the operations of the method 1400 may be performed by a wireless device as described herein with reference to FIGS. 1 through 8. In some examples, a wireless device may execute a set of instructions to control the functional elements of the wireless device to perform the described functions. Additionally, or alternatively, the wireless device may perform aspects of the described functions using special-purpose hardware.

At 1405, the method may include outputting, to a second wireless device, a set of messages. The operations of 1415 may be performed in accordance with examples as disclosed herein. In some examples, aspects of the operations of 1415 may be performed by a feedback component 750 as described herein with reference to FIG. 7.

At 1410, the method may include obtaining a message including an encoded first set of bits that are encoded using a first subcode of a set of multiple subcodes, where the first set of bits includes feedback bits that are indicative of whether the second wireless device successfully decoded each message of the set of messages. The operations of 1410 may be performed in accordance with examples as disclosed herein. In some examples, aspects of the operations of 1405 may be performed by a decoding component 740 as described herein with reference to FIG. 7.

At 1415, the method may include decoding the encoded first set of bits using the first subcode that is mapped to a first message bit combination of a set of multiple message bit combinations in accordance with a subcode mapping scheme, each of the set of multiple message bit combinations having a first quantity of bits, where the subcode mapping scheme is based at least in part on a set of multiple communication probability metrics for the set of multiple message bit combinations and a set of multiple error probability metrics for the set of multiple subcodes that includes the first subcode. The operations of 1410 may be performed in accordance with examples as disclosed herein. In some examples, aspects of the operations of 1410 may be performed by a decoding component 740 as described herein with reference to FIG. 7.

The following provides an overview of aspects of the present disclosure:

Aspect 1: A method by a first wireless device, comprising: obtaining a first set of bits having a first message bit combination that includes a first quantity of bits for inclusion in a message to be transmitted by the first wireless device; encoding the first set of bits using a first subcode that is mapped to the first message bit combination of a plurality of message bit combinations in accordance with a subcode mapping scheme, each of the plurality of message bit combinations having the first quantity of bits, wherein the subcode mapping scheme is based at least in part on a plurality of communication probability metrics for the plurality of message bit combinations and a plurality of error probability metrics for a plurality of subcodes that comprises the first subcode; and outputting the message comprising the encoded first set of bits.

Aspect 2: The method of aspect 1, wherein the subcode mapping scheme indicates a plurality of indexes, a first index of the plurality of indexes maps the first set of bits to the first message bit combination, and the plurality of indexes are based at least in part on an ordering of the plurality of communication probability metrics for the plurality of message bit combinations.

Aspect 3: The method of any of aspects 1 through 2, wherein the subcode mapping scheme maps the plurality of message bit combinations ordered in accordance with first sequential order of a respective communication probability metric for each of the plurality of message bit combinations, to the plurality of subcodes ordered in accordance with a second sequential order of a respective error probability metric for each of the plurality of subcodes, the second sequential order is reverse of the first sequential order.

Aspect 4: The first wireless device of any of aspects 1 through 3, wherein the subcode mapping scheme maps one or more first message bit combinations, with higher communication probability metrics than one or more second message bit combinations, to one or more first subcodes with lower error probability metrics than one or more second subcodes, and the one or more second message bit combinations, with lower communication probability metrics than the one or more first message bit combinations, to the one or more second subcodes with higher error probability metrics than the one or more first subcodes.

Aspect 5: The method of any of aspects 1 through 4, wherein the subcode mapping scheme maps the plurality of message bit combinations ordered sequentially, using a respective communication probability metric for each of the plurality of message bit combinations, to a plurality of sequential indexes, and each index of the plurality of sequential indexes to a respective subcode of the plurality of subcodes ordered sequentially using a respective error probability metric.

Aspect 6: The method of aspect 5, wherein the plurality of subcodes are ordered such that a subcode with a lowest error probability metric among the plurality of subcodes is mapped to a lowest index of the plurality of sequential indexes resulting in a LSB of the lowest index being applicable to the subcode with the lowest error probability metric.

Aspect 7: The method of any of aspects 5 through 6, wherein the plurality of message bit combinations are ordered sequentially from a highest communication probability metric to a lowest communication probability metric, each respective set of bits for each index of the plurality of sequential indexes are ordered from a MSB to a LSB such that a first bit position in each respective set of bits is the MSB and a last bit position in each respective set of bits is the LSB, and the plurality of subcodes are ordered from a highest error probability metric to a lowest error probability metric.

Aspect 8: The method of any of aspects 5 through 6, wherein the plurality of message bit combinations are ordered sequentially from a highest communication probability metric to a lowest communication probability metric, each respective set of bits for each index of the plurality of sequential indexes are ordered from a LSB to a MSB such that a first bit position in each respective set of bits is the LSB and a last bit position in each respective set of bits is the MSB, and the plurality of subcodes are ordered from a lowest error probability metric to a highest error probability metric.

Aspect 9: The method of any of aspects 5 through 8, wherein the plurality of message bit combinations are ordered sequentially from a highest communication probability to a lowest communication probability metric, each respective set of bits for each index of the plurality of sequential indexes are ordered from a LSB to a MSB such that a first bit position in each respective set of bits is the LSB and a last bit position in each respective set of bits is the MSB, and the plurality of subcodes are included in a generator matrix with a modified Reed Muller code ordering.

Aspect 10: The method of any of aspects 5 through 9, wherein the subcode mapping scheme maps a MSB of each index of the plurality of sequential indexes to a first bit location with lower reliability than a second bit location in each subcode of the plurality of subcodes, and a LSB of each index of the plurality of sequential indexes to the second bit location with a higher reliability than the first bit location, each subcode is a respective polar code, the subcode mapping scheme results in a respective MSB of each index being mapped to a least reliable bit location in a respective polar code and a respective LSB of each index being mapped to a respective most reliable bit location in the respective polar code.

Aspect 11: The method of aspect 10, wherein the subcode mapping scheme maps a CRC bit to a respective most reliable location in each polar code of the plurality of subcodes.

Aspect 12: The method of any of aspects 5 through 9, wherein the subcode mapping scheme maps a MSB of each index of the plurality of sequential indexes to a first bit location with lower reliability than a second bit location in each subcode of the plurality of subcodes, and a LSB of each index of the plurality of sequential indexes to the second bit location with a higher reliability than the first bit location, each subcode is a respective polar code, the subcode mapping scheme results in a respective MSB of each index being mapped to a least reliable bit location in a respective polar code and a respective LSB of each index being mapped to a respective most reliable bit location in the respective polar code.

Aspect 13: The method of any of aspects 1 through 12, further comprising: outputting, to a second wireless device, control information comprising an indication of the subcode mapping scheme.

Aspect 14: The method of any of aspects 1 through 13, further comprising: obtaining, from a second wireless device, control information comprising an indication of the subcode mapping scheme.

Aspect 15: The method of any of aspects 1 through 14, wherein the plurality of error probability metrics comprises a respective minimum distance metric for each of the plurality of subcodes.

Aspect 16: The method of any of aspects 1 through 15, wherein the plurality of error probability metrics comprises a respective weight metric for each of the plurality of subcodes.

Aspect 17: The method of any of aspects 1 through 16, wherein the plurality of error probability metrics comprises a respective probability of bit error or block error in an AWGN channel.

Aspect 18: The method of any of aspects 1 through 17, wherein the plurality of communication probability metrics comprises a respective communication likelihood for a message corresponding to each of the plurality of message bit combinations.

Aspect 19: The method of any of aspects 1 through 18, wherein each of the plurality of subcodes comprises a Reed Muller error correcting subcode.

Aspect 20: The method of any of aspects 1 through 19, further comprising: monitoring for a set of messages to be transmitted by a second wireless device, wherein the first set of bits comprises feedback bits that are indicative of whether the first wireless device successfully decoded each message of the set of messages.

Aspect 21: A method by a first wireless device, comprising: obtaining a message comprising an encoded first set of bits that are encoded using a first subcode of a plurality of subcodes; and decoding the encoded first set of bits using the first subcode that is mapped to a first message bit combination of a plurality of message bit combinations in accordance with a subcode mapping scheme, each of the plurality of message bit combinations having a first quantity of bits, wherein the subcode mapping scheme is based at least in part on a plurality of communication probability metrics for the plurality of message bit combinations and a plurality of error probability metrics for the plurality of subcodes that comprises the first subcode.

Aspect 22: The method of aspect 21, wherein the subcode mapping scheme indicates a plurality of indexes, a first index of the plurality of indexes maps the first set of bits to the first message bit combination, and the plurality of indexes are based at least in part on an ordering of the plurality of communication probability metrics for the plurality of message bit combinations.

Aspect 23: A first wireless device comprising one or more memories storing processor-executable code, and one or more processors coupled with the one or more memories and individually or collectively operable to execute the code to cause the first wireless device to perform a method of any of aspects 1 through 20.

Aspect 24: A first wireless device comprising at least one means for performing a method of any of aspects 1 through 20.

Aspect 25: A non-transitory computer-readable medium storing code the code comprising instructions executable by one or more processors to perform a method of any of aspects 1 through 20.

Aspect 26: A first wireless device comprising one or more memories storing processor-executable code, and one or more processors coupled with the one or more memories and individually or collectively operable to execute the code to cause the first wireless device to perform a method of any of aspects 21 through 22.

Aspect 27: A first wireless device comprising at least one means for performing a method of any of aspects 21 through 22.

Aspect 28: A non-transitory computer-readable medium storing code the code comprising instructions executable by one or more processors to perform a method of any of aspects 21 through 22.

It should be noted that the methods described herein describe possible implementations. The operations and the steps may be rearranged or otherwise modified and other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, a graphics processing unit (GPU), a neural processing unit (NPU), an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Any functions or operations described herein as being capable of being performed by a processor may be performed by multiple processors that, individually or collectively, are capable of performing the described functions or operations.

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk, and Blu-ray disc. Disks may reproduce data magnetically, and discs may reproduce data optically using lasers. Combinations of the above are also included within the scope of computer-readable media. Any functions or operations described herein as being capable of being performed by a memory may be performed by multiple memories that, individually or collectively, are capable of performing the described functions or operations.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The term “determine” or “determining” encompasses a variety of actions and, therefore, “determining” can include calculating, computing, processing, deriving, investigating, looking up (such as via looking up in a table, a database, or another data structure), ascertaining, and the like. Also, “determining” can include receiving (e.g., receiving information), accessing (e.g., accessing data stored in memory), and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label or other subsequent reference label.

The description set forth herein, in connection with the appended drawings, describes example configurations and does not represent all the examples that may be implemented or that are within the scope of the claims. The term “example” used herein means “serving as an example, instance, or illustration” and not “preferred” or “advantageous over other examples.” The detailed description includes specific details for the purpose of providing an understanding of the described techniques. These techniques, however, may be practiced without these specific details. In some figures, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A first wireless device, comprising:
one or more memories storing processor-executable code; and
one or more processors coupled with the one or more memories and individually or collectively operable to execute the code to cause the first wireless device to:
obtain a first set of bits having a first message bit combination that includes a first quantity of bits for inclusion in a message to be transmitted by the first wireless device;
encode the first set of bits using a first subcode that is mapped to the first message bit combination of a plurality of message bit combinations in accordance with a subcode mapping scheme, each of the plurality of message bit combinations having the first quantity of bits, wherein the subcode mapping scheme is based at least in part on a plurality of communication probability metrics for the plurality of message bit combinations and a plurality of error probability metrics for a plurality of subcodes that comprises the first subcode; and
output the message comprising the encoded first set of bits.

2. The first wireless device of claim 1, wherein:
the subcode mapping scheme indicates a plurality of indexes,
a first index of the plurality of indexes maps the first set of bits to the first message bit combination, and
the plurality of indexes are based at least in part on an ordering of the plurality of communication probability metrics for the plurality of message bit combinations.

3. The first wireless device of claim 1, wherein the subcode mapping scheme maps:
the plurality of message bit combinations ordered in accordance with first sequential order of a respective communication probability metric for each of the plurality of message bit combinations, to
the plurality of subcodes ordered in accordance with a second sequential order of a respective error probability metric for each of the plurality of subcodes, wherein the second sequential order is reverse of the first sequential order.

4. The first wireless device of claim 1, wherein the subcode mapping scheme maps:
one or more first message bit combinations, with higher communication probability metrics than one or more second message bit combinations, to one or more first subcodes with lower error probability metrics than one or more second subcodes, and
the one or more second message bit combinations, with lower communication probability metrics than the one or more first message bit combinations, to the one or more second subcodes with higher error probability metrics than the one or more first subcodes.

5. The first wireless device of claim 1, wherein the subcode mapping scheme maps:
the plurality of message bit combinations ordered sequentially, using a respective communication probability metric for each of the plurality of message bit combinations, to a plurality of sequential indexes, and
each index of the plurality of sequential indexes to a respective subcode of the plurality of subcodes ordered sequentially using a respective error probability metric.

6. The first wireless device of claim 5, wherein the plurality of subcodes are ordered such that a subcode with a lowest error probability metric among the plurality of subcodes is mapped to a lowest index of the plurality of sequential indexes resulting in a least significant bit of the lowest index being applicable to the subcode with the lowest error probability metric.

7. The first wireless device of claim 5, wherein:
the plurality of message bit combinations are ordered sequentially from a highest communication probability metric to a lowest communication probability metric,
each respective set of bits for each index of the plurality of sequential indexes are ordered from a most significant bit to a least significant bit such that a first bit position in each respective set of bits is the most significant bit and a last bit position in each respective set of bits is the least significant bit, and
the plurality of subcodes are ordered from a highest error probability metric to a lowest error probability metric.

8. The first wireless device of claim 5, wherein:
the plurality of message bit combinations are ordered sequentially from a highest communication probability metric to a lowest communication probability metric,
each respective set of bits for each index of the plurality of sequential indexes are ordered from a least significant bit to a most significant bit such that a first bit position in each respective set of bits is the least significant bit and a last bit position in each respective set of bits is the most significant bit, and
the plurality of subcodes are ordered from a lowest error probability metric to a highest error probability metric.

9. The first wireless device of claim 5, wherein:
the plurality of message bit combinations are ordered sequentially from a highest communication probability to a lowest communication probability,
each respective set of bits for each index of the plurality of sequential indexes are ordered from a least significant bit to a most significant bit such that a first bit position in each respective set of bits is the least significant bit and a last bit position in each respective set of bits is the most significant bit, and
the plurality of subcodes are included in a generator matrix with a modified Reed Muller code ordering.

10. The first wireless device of claim 5, wherein each respective set of bits for each index of the plurality of sequential indexes are ordered from a most significant bit to a least significant bit wherein the subcode mapping scheme maps:
a most significant bit of each index of the plurality of sequential indexes to a first bit location with lower reliability than a second bit location in each subcode of the plurality of subcodes, and
a least significant bit of each index of the plurality of sequential indexes to the second bit location with a higher reliability than the first bit location, wherein each subcode is a respective polar code, wherein the subcode mapping scheme results in a respective most significant bit of each index being mapped to a least reliable bit location in a respective polar code and a respective least significant bit of each index being mapped to a respective most reliable bit location in the respective polar code.

11. The first wireless device of claim 10, wherein the subcode mapping scheme maps a cyclic redundancy check bit to a respective most reliable location in each polar code of the plurality of subcodes.

12. The first wireless device of claim 5, wherein each respective set of bits for each index of the plurality of sequential indexes are ordered from a least significant bit to a most significant bit, and wherein the subcode mapping scheme maps:
a most significant bit of each index of the plurality of sequential indexes to a first bit location with lower reliability than a second bit location in each subcode of the plurality of subcodes, and
a least significant bit of each index of the plurality of sequential indexes to the second bit location with a higher reliability than the first bit location, wherein each subcode is a respective polar code, wherein the subcode mapping scheme results in a respective most significant bit of each index being mapped to a least reliable bit location in a respective polar code and a respective least significant bit of each index being mapped to a respective most reliable bit location in the respective polar code.

13. The first wireless device of claim 1, wherein the one or more processors are individually or collectively further operable to execute the code to cause the first wireless device to:
output, to a second wireless device, control information comprising an indication of the subcode mapping scheme.

14. The first wireless device of claim 1, wherein the one or more processors are individually or collectively further operable to execute the code to cause the first wireless device to:
obtain, from a second wireless device, control information comprising an indication of the subcode mapping scheme.

15. The first wireless device of claim 1, wherein the plurality of error probability metrics comprises a respective minimum distance metric for each of the plurality of subcodes, or a respective weight metric for each of the plurality of subcodes, or a respective probability of bit error or block error in an additive white gaussian noise (AWGN) channel for each of the plurality of subcodes.

16. The first wireless device of claim 1, wherein the plurality of communication probability metrics comprises a respective communication likelihood for a message corresponding to each of the plurality of message bit combinations.

17. The first wireless device of claim 1, wherein each of the plurality of subcodes comprises a Reed Muller error correcting subcode.

18. The first wireless device of claim 1, wherein the one or more processors are individually or collectively further operable to execute the code to cause the first wireless device to:
monitor for a set of messages to be transmitted by a second wireless device, wherein the first set of bits comprises feedback bits that are indicative of whether the first wireless device successfully decoded each message of the set of messages.

19. A first wireless device, comprising:
one or more memories storing processor-executable code; and
one or more processors coupled with the one or more memories and individually or collectively operable to execute the code to cause the first wireless device to:
obtain a message comprising an encoded first set of bits that are encoded using a first subcode of a plurality of subcodes; and
decode the encoded first set of bits using the first subcode that is mapped to a first message bit combination of a plurality of message bit combinations in accordance with a subcode mapping scheme, each of the plurality of message bit combinations having a first quantity of bits, wherein the subcode mapping scheme is based at least in part on a plurality of communication probability metrics for the plurality of message bit combinations and a plurality of error probability metrics for the plurality of subcodes that comprises the first subcode.

20. A method for wireless communications at a first wireless device, comprising:
obtaining a first set of bits having a first message bit combination that includes a first quantity of bits for inclusion in a message to be transmitted by the first wireless device;
encoding the first set of bits using a first subcode that is mapped to the first message bit combination of a plurality of message bit combinations in accordance with a subcode mapping scheme, each of the plurality of message bit combinations having the first quantity of bits, wherein the subcode mapping scheme is based at least in part on a plurality of communication probability metrics for the plurality of message bit combinations and a plurality of error probability metrics for a plurality of subcodes that comprises the first subcode; and
outputting the message comprising the encoded first set of bits.
